(19) United States
(12) Patent Application Publication
(10) Pub. No.: US 2006/0127599 A1
(43) Pub. Date: Jun. 15, 2006

(54) Process and apparatus for preparing a diamond substance

(76) Inventor: Gregory J. Wojak, Scottsdale, AZ (US)

Correspondence Address: HOWARD J. GREENWALD P.C., 349 W. COMMERCIAL STREET SUITE 2490, EAST ROCHESTER, NY, 14445-2408, US

(21) Appl. No.: 11/342,494

(22) Filed: Jan. 30, 2006

Related U.S. Application Data
(63) Continuation-in-part of application No. 10/364,863, filed on Feb. 11, 2003, now abandoned.
(60) Provisional application No. 60/356,304, filed on Feb. 12, 2002.

(51) Int. Cl. C01B 31/06; C23C 16/00; B01J 3/06; H05H 1/24; H01L 21/31

(52) U.S. Cl. 427/569; 423/446; 427/248.1; 438/790

(57) ABSTRACT

Disclosed in this specification is a process and apparatus for producing a diamond substance. A first mixture comprised of oxygen and a hydrocarbon gas is formed in the first inner nozzle. The first mixture is ignited to produce a flame core. A second mixture comprised of hydrogen and oxygen is formed in an outer nozzle; the second mixture is ignited to produce a flame sheath. The flame sheath is disposed around the flame core so that the flame sheath surrounds the flame core and shields the flame core from the ambient atmosphere; thereby producing a composite flame; and the composite flame is contacted with a substrate.

### CROSS-REFERENCE TO RELATED PATENT APPLICATION

This application is a continuation-in-part of applicants' co-pending patent application U.S. Ser. No. 10/364,863 (filed on Feb. 11, 2003), priority for which was based upon applicant's provisional application U.S. Ser. No. 60/356,304, filed on Feb. 12, 2002. The content of each of the aforementioned patents and patent applications is hereby incorporated by reference into this specification.

### FIELD OF THE INVENTION

A composite diamond substrate comprised of a diamond substance coated with a thin film, a process and apparatus for producing such diamond substance in which a composite flame comprised of a core of hydrocarbon and oxygen and sheath of hydrogen, oxygen, and water deposits diamond onto a substrate and thereafter coating such diamond substance with a thin film layer comprising an adhesion layer, diffusion barrier layer, thermal barrier layer, chemical reactivity barrier layer, oxidation-reduction barrier layer, and combinations thereof.

### BACKGROUND OF THE INVENTION

It is known that one can form a diamond substance by creating a plasma state within a hydrocarbon gas mixture by the well-known “combustion torch system.” Typically a hydrocarbon gas, such as methane, ethane, or acetylene, is reacted with oxygen to form a flame, and the flame products are then deposited onto a substrate.

One significant disadvantage of the combustion torch process is that an inhomogeneous product is formed, having substantially good quality near the center of the flame and poor quality at is periphery. The diamond substances produced deposit non-uniformly along the surface, concentrating in certain areas and thus requiring a grinding step to obtain the flat surfaces desired by many users. This grinding step is inefficient, wasting expensive product and raw materials, as well as requiring additional process steps, labor, energy, equipment and material. In the novel process of this invention, diamond substrates are produced of a size and shape superior to those produced by other processes. The diamond substrates produced by the novel process of this invention have a homogenous mixture, uniform distribution and a relatively flat surface, reducing or eliminating the need for grinding.

Additionally, the homogeneity and larger size of the composite diamond substrate product elevates the composition to a material meeting the strict materials requirements necessary in the semi-conductor, optical and aerospace industries. Prior art processes are unable to coat diamond substances on large target materials because they are limited by the area covered by the active plasma. Plasmas covering large areas tend to be unstable and difficult to control. This instability causes large inhomogeneities in both the quantity and quality of the deposit, which result in a final product of insufficient quality for most applications.

Prior art processes typically require the addition of an external energy source or energy field such as microwave radiation, laser irradiation, or an electric arc. Such electrical or electromagnetic sources of energy couple inefficiently with the neutral (non-ionized) matter (carbon, hydrogen, etc.) provided to form the diamond, and only a small percentage of input energy is absorbed to create plasma. Plasma itself couples well with energy produced by electrical or electromagnetic sources, and plasmas stimulated by such energies quickly become very hot, often in the range of hundreds to thousands of electron volts. These temperatures are usually far higher than needed, as most chemical reactions, including those necessary to produce diamond, occur at temperatures of less than three electron volts. The temperature of the plasma may be reduced through the addition of colder neutral matter, usually a gas. The plasma transfers energy kinetically to the gas through a process termed “thermalization”. However, the thermalization process also significantly increases the amount of plasma that reverts back into neutral matter, and higher levels of input power are become necessary to sustain the plasma. Thus, it is the inefficient energy coupling, unnecessarily high plasma temperatures, and the high power input needed to sustain a plasma undergoing thermalization, that make approaches based on external electrical or electromagnetic sources inherently inefficient. In the novel process of this invention, the source of energy and source of carbon and hydrogen are identical. The oxidation of the hydrocarbon source produces plasma through chemical energy, eliminating the need for an external energy source. In embodiments where an external electrical or electromagnetic energy field is applied to enhance growth rates and uniformity during deposition, the energy required is substantially less than that required for a process which relies exclusively on an external energy source. There is no need for the external energy source to couple to neutral matter, and the collapse of the plasma during thermalization is non-existent since plasma is continuously supplied by the chemical reaction.

Diamond substrates produced by prior art methods have inherent application limitations due to their specific material properties. In particular, reactivity at the surface of the diamond substance with other materials (such as semiconductors) produce well-known defects and traps at the interface of the diamond with other material. The novel composite diamond substrate of the present invention addresses these problems in the art by coating such diamond substance with a thin film layer comprising a diffusion barrier layer, thermal barrier layer, chemical reactivity barrier layer, oxidation-reduction barrier layer, binding and adhesion layer, and combinations thereof. Applicant discloses thin film compositions that have these desired properties and methods of deposition of these thin films on a diamond.

Additionally, adhesion to the diamond substance has been problematic. The surface of diamond has a very high surface energy and is typically not reactive with most materials, i.e., materials that do not form strong carbide compounds. Applicant discloses methods of binding his novel composite diamond substrate with thin film to a semi-conductor, as well as to other desired components.

It is an object of this invention to provide a process which produces a high quality diamond substance which is substantially more homogeneous than prior art processes.

It is an object of this invention to provide a process which produces a high quality diamond substance which has a substantially more uniform distribution than prior art processes, thus reducing or eliminating the need for grinding.

It is an object of this invention to provide a process with substantially lower materials and production costs than prior art processes, offering significant economic advantages for the manufacturer. In particular, the capital equipment costs are substantially less than prior art processes involving vacuum chambers.

It is an object of this invention to provide a process for forming a diamond substrate, wherein the source of energy and source of carbon and hydrogen are identical, eliminating the need for an external energy source. In embodiments where an external electrical or electromagnetic energy field is applied to enhance growth rates and uniformity during deposition, the energy required is substantially less than that required for a process which relies exclusively on an external energy source.

It is an object of this invention to provide a process that is more easily scalable than prior art processes.

It is an object of this invention to provide a process which produces a high quality diamond substance which has a substantially longer useful life than prior art processes.

It is an object of this invention to provide a process which produces a high quality diamond substance which is substantially flatter than prior art processes.

It is also an object of the present invention to provide a composite diamond substrate and process for making the same that comprises a chemical reactivity barrier layer.

It is also an object of the present invention to provide a composite diamond substrate and process for making the same that comprises an oxidation-reduction barrier layer.

It is also an object of the present invention to provide a composite diamond substrate and process for making the same that comprises a diffusion barrier layer.

It is also an object of the present invention to provide a composite diamond substrate and process for making the same that comprises a thermal barrier layer.

It is also an object of the present invention to provide a composite diamond substrate and process for making the same that comprises an adhesion layer.

It is also an object of the present invention to provide a composite diamond substrate and process for making the same that comprises a multi-purpose barrier layer against two or more processes such as thermal degradation, chemical degradation, oxidation, reduction, and diffusion.

It is also an object of the present invention to provide a composite diamond substrate and process for making the same that eliminates the need for an external energy source or energy field.

It is also an object of the present invention to provide a composite diamond substrate and process for making the same that eliminates the need for a vacuum chamber.

It is also an object of the present invention to provide a composite diamond substrate and process for making the same that is scalable on an industrial level.

It is also an object of the present invention to provide a composite diamond substrate and process for making the same that is susceptible of low manufacturing costs with regard to labor and materials, and which accordingly then produces a product susceptible of low prices for the consuming public, thereby making it economically available to the buying public.

It is also an object of the present invention to provide a composite diamond substrate and process for making the same that comprises a high quality lightweight material with an engineered microstructure having superior specific strength.

It is also an object of the present invention to provide a composite diamond substrate and process for making the same that comprises a high quality lightweight material with superior performance in extreme chemical and thermal environments.

Whereas there may be many embodiments of the present invention, each embodiment may meet one or more of the foregoing recited objects in any combination. It is not intended that each embodiment will necessarily meet each objective.

### SUMMARY OF THE INVENTION

One embodiment of the present invention is a process of producing a diamond substance, comprising the steps of forming a first mixture comprised of oxygen gas and a hydrocarbon gas, wherein said hydrocarbon gas contains from about one percent to about ten percent molar excess of carbon for each mole of oxygen present in such first mixture; igniting said first mixture to produce a flame core; forming a second mixture comprised of hydrogen and oxygen, wherein said second mixture is comprised of a molar excess of said hydrogen over the moles of said oxygen present in the second mixture, said second mixture contains up to about 10 volume percent of hydrocarbon gas; igniting said second mixture to produce a flame sheath; disposing said flame sheath around said flame core so that said flame sheath surrounds said flame core and shields said flame core from the atmosphere, thereby producing a composite flame; and contacting said composite flame with a substrate.

Another embodiment of this invention is comprised of a composite diamond substrate comprised of a diamond substance coated with a thin film and a process for producing such diamond substance in which a composite flame comprised of a core of hydrocarbon and oxygen and sheath of hydrogen, oxygen, and water deposits diamond onto a substrate and thereafter coating such diamond substance with a thin film layer comprising an adhesion layer, diffusion barrier layer, thermal barrier layer, chemical reactivity barrier layer, oxidation-reduction barrier layer, and combinations thereof.

Such process steps may be individually configured and correlated with respect to each other so as to attain the desired objective.

Thus having broadly outlined the more important features of the present invention in order that the detailed description thereof may be better understood, and that the present contribution to the art may be better appreciated, there are, of course, additional features of the present invention that will be described herein and will form a part of the subject matter of the claims appended to this specification.

In this respect, before explaining at least one embodiment of the invention in detail, it is to be understood that the invention is not limited in its application to the details and the arrangements of the process steps set forth in the following description or illustrated in the drawings. The present invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is to be understood that the aforementioned description is illustrative only and that changes can be made in the apparatus, in the ingredients and their proportions, and in the sequence of combinations and process steps, as well as in other aspects of the invention discussed herein, without departing from the scope of the invention as defined in the following claims. It is important, therefore, that the claims be regarded as including such equivalent construction insofar as they do not depart from the spirit and scope of the conception regarded as the present invention.

These and other objectives of the invention, which will become apparent from the following description, have been achieved by a novel process for producing a diamond substance. The process may include additional steps of applying thin film coatings to change the functional properties of the diamond substance, for example adherence, chemical reactivity, thermal conductivity, resistance to heat, etc.

### BRIEF DESCRIPTION OF THE DRAWINGS

The invention will be described by reference to the specification and the enclosed drawings, in which like elements are identified by like numerals, and in which:

FIG. 1 is a schematic illustrating a composite flame deposition head used for the deposition of diamond;

FIG. 2 is an isometric projection schematic with a cut-away side illustrating one preferred embodiment of the invention consisting of a deposition head containing eight sub-nozzles;

FIG. 3 is a cut-away side schematic illustrating a torch sub-nozzle assembly of one preferred embodiment of the invention;

FIG. 4 is a cut-away front schematic illustrating one preferred embodiment of the invention consisting of a deposition head containing eight sub-nozzles;

FIG. 5 is a schematic illustrating one position of the mechanical control of the flow of gas from the preferred embodiment of the invention;

FIG. 6 is a schematic illustrating another position of the mechanical control of the flow of gas from the preferred embodiment of the invention;

FIG. 7 is a schematic illustrating the deposition head and the material deposited from a conventional combustion torch system;

FIG. 8 is a schematic illustrating the deposition head and the material deposited from the invention;

FIG. 9 is a schematic illustrating from a top view the material deposited from a conventional combustion torch system and from the invention;

FIG. 10 is a schematic illustrating from a cross-sectional side view of the deposition heads and the material deposited from a conventional combustion torch system and from the invention;

FIG. 11 is a schematic illustrating from a different cross-sectional side view of the deposition heads and the material deposited from a conventional combustion torch system and from the invention;

FIG. 12 is a schematic illustrating an isometric projection the deposition head and its position and movement in relation to a substrate on which the deposition takes place;

FIG. 13 is a schematic illustrating a top view of the deposition head and its position and movement in relation to a substrate on which the deposition takes place;

FIG. 14 is a schematic illustrating the ability of the deposition head to be rotated on its axis;

FIG. 15 is a schematic illustrating the ability of the sub-nozzles of the deposition head to be moved individually in the vertical direction in relation to the substrate on which the deposition takes place;

FIG. 16 is a schematic illustrating substrate warping as a result of heat input from a flame;

FIG. 17 is a schematic illustrating a solution to substrate warping as a result of using the heat input of two flames;

FIG. 18 is a schematic illustrating an aspect of the invention used to control the temperature of the deposition;

FIG. 19 is a schematic illustrating a method and apparatus for plasma enhancement of the flame;

FIG. 20 is a schematic illustrating an arrangement of electrodes used in the apparatus for plasma enhancement of the flame;

FIG. 21 shows schematic diagrams illustrating a method of control and feedback for control of the electrical currents used in the plasma enhancement of the flame;

FIG. 22 A and FIG. 22B are schematic diagrams of a diamond substrate of the present invention;

FIG. 23A and FIG. 24B are schematic illustrations of a diamond substrate that utilize adhesion layers to bond it to a second substrate;

FIG. 24A and FIG. 24B are depictions of a barrier layer of the present invention;

FIG. 25A and FIG. 25B are depictions of a thermal barrier layer and a diffusion barrier layer, respectively; and

FIG. 26A and FIG. 26B illustrate the use of a chemical reactivity barrier layer and an oxidation-reduction barrier layer.

### DESCRIPTION OF THE PREFERRED EMBODIMENTS

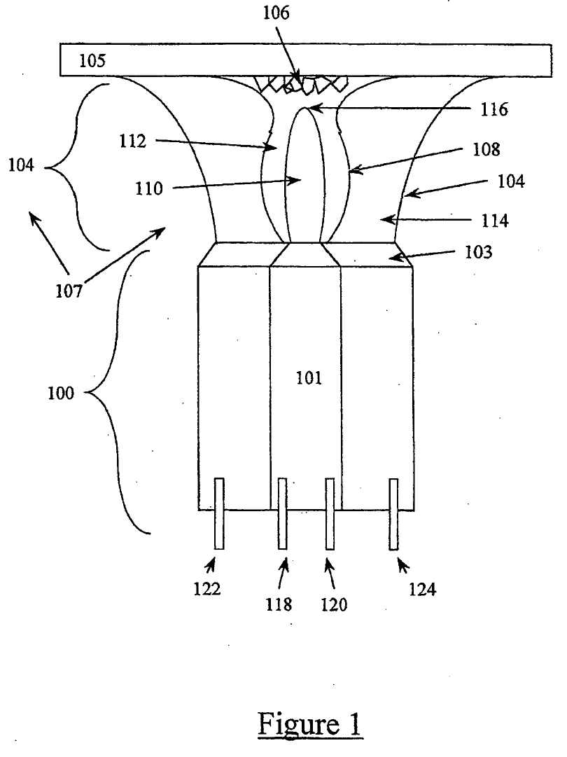

FIG. 1 is a schematic representation of an oxyacetylene torch 100 producing a flame 104 impinging upon a substrate 105. Although the oxyacetylene torch 100 is not necessarily the preferred burner used in applicant's process, it is shown in FIG. 1 for the sake of simplicity in representing the preferred process.

The use of an oxyacetylene torch in producing diamond material is well known. Reference may be had, e.g., to U.S. Pat. No. 5,340,401 (diamond deposition cell), U.S. Pat. No. 5,182,093 (diamond deposition cell), U.S. Pat. No. 5,674,572 (enhanced adherence of diamond coatings), U.S. Pat. No. 5,418,018 (chemical vapor deposition of diamond films), and the like. The entire disclosure of each of these United States patents is hereby incorporated by reference into this specification.

As is known to those skilled in the art, an oxyacetylene torch is one embodiment of a “combustion torch.” A “combustion torch” is any torch that utilizes a combustible hydrocarbon gas and oxygen. The use of such a “combustion torch” in producing diamond material is also well known. Reference may be had, e.g., to U.S. Pat. No. 5,338,364 (process for producing diamond film), U.S. Pat. No. 5,217,700 (apparatus for producing diamond film), U.S. Pat. No. 5,863,604 (combustion chemical vapor deposition of diamond films and coatings), and the like. The contents of the aforementioned patents are herby incorporated by reference into this specification.

Referring again to FIG. 1, and in the preferred embodiment depicted therein, an oxyacetylene torch 100 comprised of inner nozzle 101 and outer nozzle 103 is depicted.

The torch 100 depicted in FIG. 1 produces a composite flame 104, i.e., a flame with more than one flame region, each of which has a different chemical composition.

Referring again to FIG. 1, the composite flame 104 produced by torch 100 impinges upon the substrate 105 and deposits diamond material 106 thereon.

The Flame Core 108

In the preferred embodiment depicted in FIG. 1, the composite flame 104 is comprised of a core 108. The flame core 108, in turn, is comprised of an inner cone, also know as the inner cone 110, and an outer cone also known as a feather 112.

Referring again to FIG. 1, and in the preferred embodiment depicted therein, it will be seen that flame sheath 114 completely surrounds the flame core 108 so that no portion of the flame core 108 is exposed to the ambient atmosphere 107.

As is known to those skilled in the art, a flame core is the central part of a flame in which the primary chemical reaction(s) take place. Within the flame core 108 is the inner cone 110 (which is the hottest part of the flame core, and in which plasma is generated), and a feather section.

Typically the inner cone 110 of the core 108 has a different color than the sheath 114. In one embodiment, the inner cone 110 of core 108 has a violet color, and the sheath 114 has an orange color.

The inner cone 110 of the core 108 preferably is at a specified distance from the substrate 105. In general, the leading edge 116 of the inner cone 110 is disposed no more than about 5 millimeters from the substrate 105.

The inner cone 110 of the core 108 is preferably produced by the incomplete combustion of hydrocarbon gas(es) and oxygen, which are fed into nozzle 101 in the direction of arrows 118 and 120. In order to properly position the leading edge 116 of the inner cone 110 vis-à-vis the substrate 105, one may first flow the hydrocarbon gas and the oxygen into the nozzle 101 and combust such gases and, thereafter, with reference to the flame thus produced, position the leading edge 116 of such flame at the proper distance from such substrate 105. Thereafter, one may then combust gases sufficient to create the sheath 114.

Referring again to FIG. 1, and in the preferred embodiment depicted therein, one may feed any combustible hydrocarbon gas into nozzle 101, provided that the combustion of such gas preferably produces substantial amounts of energy. In one embodiment, such combustion produces flame temperatures in excess of 2,000 degrees Centigrade.

By way of illustration and not limitation, one may use gases such as, e.g., benzene, propadiene, map gas, acetylene, and the like. In general, the hydrocarbon gas fed into nozzle 101 preferably has a heat of formation of at least about 20 kilocalories/gram-mole.

It also preferred that the hydrocarbon gas fed into nozzle 101 preferably has a molecular weight less than about 85 AMU's and, more preferably, less than 50 AMU's. In one embodiment, the molecular weight of the hydrocarbon gas is less than about 30 AMU's.

It is preferred that the flame temperature of the hydrocarbon gas, when combusted with at least an equimolar amount of oxygen, be at least about 2,000 degrees Celsius and, more preferably, be at least about 2,300 degrees Celsius. Means for determining the flame temperature of a hydrocarbon gas are well known. Reference may be had, e.g., to U.S. Pat. Nos. 6,135,760; 6,071,114, and the like. The entire disclosure of each of these United States patents is hereby incorporated by reference into this specification.

One may use mixtures of two or more such hydrocarbon gases. Additionally, one may feed hydrogen into nozzle 101 provided that the flame produced has a high enough flame temperature.

By way of illustration, one may use Brown's gas in combination with one or more of the aforementioned hydrocarbon gases in nozzle 101. This gas is well known and is described, e.g., in U.S. Pat. No. 6,021,915, the entire disclosure of which is hereby incorporated by reference into this specification. As is disclosed in such patent, “The Brown's gas that is used in the present invention is itself a non-explosive mixed gas that consists of hydrogen and oxygen mixed in a molar volume ratio of 2:1, and it is obtained by electrolysis of water; and it is known that the combustion thereof causes the molecular or atomic hydrogen and oxygen to produce heat of the reaction, thereby bringing about a quite high combustion temperature. In the present invention, the Brown's gas is combusted by using a torch nozzle and an igniter or the like for producing an ignition spark, to produce a highly reducing flame of about 2,3000° C., and preferably the tip of the flame good in reactivity is brought in contact with the above mixed gas flow. The number of the Brown's gas combustion burners for bringing the Brown's gas flame in contact with the above mixed gas flow to combust the mixed gas may be 1 or 2 or more; preferably the Brown's gas combustion burners are used 2 or more, and more preferably 2 or 3 in number. Thus, the mixed gas is combusted at high temperatures. This is considered in such a way that the Brown's gas flame heats the mixed gas flow as well as interacts with active chemical species produced from the fossil fuel in the mixed gas, to combust the fossil fuel gas to generate a high temperature; this high temperature causes steam explosion of the moisture in the mixed gas, thereby combusting it as a hydrogen/oxygen gas flame (Brown's gas flame) at a high speed, and the flame propagation resulting therefrom leads to combustion throughout the mixed gas. The speed of the high-speed combustion by this steam explosion is, for example, about 6.75 times (linear velocity: 2.7 m/s) that of the combustion of propane.”

When Brown's gas is used in the process of the invention within nozzle 101, it is preferred to use at least about 60 volume percent of the Brown's gas and no more than about 40 volume percent of one or more of the hydrocarbon gases.

Regardless of the identity of the hydrocarbon gas(es) used, it is preferred that at least about 10 volume percent of hydrocarbon gas comprise the mixture present within nozzle 101.

In one embodiment, one may add one or more “doping gases” to the hydrocarbon gas and/or the hydrocarbon gas mixture fed to nozzle 101. As will be apparent, the function of such doping gases is to provide electrical conductivity to the diamond material produced. Suitable doping gases include, e.g., silane, deuterium, deuterated boron, diborane, boron-containing gasses, halogens, phosphine phosphorous-containing gases, hydrogen sulfide, sulfur-containing gases, nitrogen, nitrogen-containing gases, and the like. In general, when a doping gas or gases is used, it is present at a concentration of less than about 1 volume percent.

The inclusion of doping gasses is meant to insert dopant atoms into the lattice of the diamond crystal within the film. These may be inserted as substitutional dopants or as interstitial dopants in the lattice, the purpose of which is to provide free charge carriers within the medium. The inclusion of suitable dopants into the substrate or into sections of the substrate makes possible numerous applications.

In one such embodiment, suitably doped diamond may be used electrodes for electrochemical processes,

In another embodiment, the inclusion of suitable dopants into the substrate may be used to produce semiconductor layers suitable for the fabrication of semiconductor devices.

In another embodiment, the inclusion of suitable dopants into the substrate may be used to produce conductive or semiconductor layers capable of modifying the capacitance and dielectric constant of the substrate, which may be suitable for the fabrication of RF semiconductor devices.

Referring again to FIG. 1, and in the preferred embodiment depicted therein, it is also preferred to feed either oxygen and/or an oxygen-containing gas in the direction of arrow 120 into nozzle 101. Thus, e.g., one may use oxygen, ozone, atomic oxygen, nitrous oxide, and/or any other oxidizing gas which, when combined with the hydrocarbon fuel, will produce a flame with the required properties. When an oxygen-containing gas is used in addition to or instead of oxygen, it is preferred to utilize a gas that will form oxygen in situ.

It is preferred to use a certain ratio of carbon and oxygen (C/O) within nozzle 101.

In general, the hydrocarbon is present in slight stoichiometric excess, there being from about 1.01 to about 1.1 moles of carbon for each mole of oxygen, based upon the conversion of carbon to carbon monoxide. The oxygen or oxygen containing gas is preferably fed into nozzle 101 at a flow rate adapted to produce the desired stociometry.

In one embodiment, in addition to the hydrocarbon gas(es) and the oxygen gas(es), one may feed growth-enhancing gas(es) into nozzle 101. Suitable growth-enhancing gases include nitrogen, halogens (such as, e.g., chlorine), diborane, silane, cyanide, oxides, ammonia, disilane, and the like. In general, when such a gas is used, it is present at a concentration of no more than about 10 volume percent. However for each growth-enhancing gas, there is a concentration at which further additions of the gas will begin to significantly degrade the quality of the diamond. At sufficiently high concentrations, these growth-enhancing gases will interfere with the chemical reaction required for diamond growth such that only graphite or other non-diamond forms of carbon will be produced. In general, when such a reaction takes place, the growth-enhancing gases is present at a concentration of more than about 10 volume percent. The gas mixture disposed within the nozzle 101 is ignited to form the flame core 108. In the process of this invention, it is preferred that flame core 108 be completely surrounded by flame sheath 114 so that no portion of flame core 108 is exposed to the atmosphere 107.

The Flame Sheath 114

The flame sheath 114 is formed by combusting a mixture of gases within the outer nozzle 103 that differs in composition from the mixture of gases within inner nozzle 101. Whereas the mixture within the outer nozzle 103 contains less than about 5 volume percent of hydrocarbon gas, the mixture within inner nozzle 101 contains at least about 10 volume percent of hydrocarbon gas.

Referring again to FIG. 1, and in the preferred embodiment depicted therein, it will be seen that the flame sheath 114 is preferably contiguous with at least a portion of flame core 108. This contiguity is not essential, and there may be a gap between the flame core 108 and the flame sheath 114, as long as the sheath 114 shields the core 108 from the atmosphere 107. This shielding spatial relationship may be achieved by using one nozzle assembly with inner and outer orifices, as shown in FIG. 1. Alternatively, one may utilize two or more separate nozzles whose flames are combined in the proper location to provide the desired composite flame.

Referring again to FIG. 1, and in the preferred embodiment depicted, the composite flame 104 is comprised of both the flame sheath 114 and the flame core 108, preferably in a ratio of at least about 55 volume percent of sheath 114, and less than about 45 volume percent of core 108, provided that the ratio, volume/volume, of said sheath 114/core 108 is generally at least about 1.5/1.

The sheath 114 is preferably at a temperature of at least about 250 degrees Celsius. In one embodiment, the temperature of the sheath 114 is from about 350 to about 650 degrees Centigrade. In another embodiment, the temperature of the sheath 114 is from about 450 to about 650 degrees Celsius.

The sheath 114 is comprised of oxygen, hydrogen, and water. The constituents of sheath 114 are fed via lines 122 and 124. The gas fed via lines 122 and 124 is collectively comprised of at least about 20 volume percent of hydrogen and oxygen, by total weight of all gases fed to nozzle 103.

The desired mixture of hydrogen and oxygen may be fed to nozzle 103, and/or one or both of said gaseous components may be formed in situ within such nozzle 103. With regard to the hydrogen and oxygen so fed to nozzle 103, or formed therein, it is preferred at least 2 moles of hydrogen is fed or formed for each mole of oxygen. In one embodiment, from about 2 to 2.2 moles of hydrogen are fed and/or formed in situ for each mole of oxygen fed.

In one embodiment, in addition to the oxygen and hydrogen fed, up to about 50 volume percent of water vapor is fed via line 122 and/or line 124.

In one embodiment, an inert gas (such as, e.g., argon) may be fed into nozzle 103. In this embodiment, it is preferred to feed less than about 20 volume percent of such insert gas to nozzle 103.

In one embodiment, hydrogen peroxide may be fed into nozzle 103 as a replacement for part or all of the water, preferably in an amount up to about 10 volume percent.

In another embodiment, ozone may be fed into nozzle 103 as a replacement for part or all of the oxygen.

In another embodiment, Brown's gas may be fed into nozzle 103 as a replacement for all or part of the oxygen and/or the hydrogen.

In another embodiment, additional hydrogen gas may be fed into nozzle 103 as a replacement for all or part of the oxygen. In this embodiment, it is preferred to add sufficient hydrogen to form a gas mixture with reducing properties.

In another embodiment, a liquid acid (such as hydrochloric acid) may be added to the water prior to the time it is fed into nozzle 103. In this embodiment, it is preferred to add sufficient acid so that the pH of the water is less than about 4.0. Without wishing to be bound to any particular theory, applicant believes that the lower the pH of the system, the more hydrogen ions are contained therein.

Without wishing to be bound to any particular theory, applicant believes that controlling the hydrogen and oxygen content in the sheath allows the user to control the growth conditions of the diamond, the degree of “hydrogen-etching”, the degree of “oxygen-etching”, and the removal of graphite from the surface of the diamond. Applicant believes that a reducing atmosphere allows reduction reactions to take place in the presence of oxygen gas, thus increasing the removal rate of graphite from the surface of the diamond.

In one embodiment, water may be introduced into nozzle 103 as a means of regulating the temperature of the sheath 114. The percent weight of water used should be below 50 percent and should generally be kept below 20 percent. It is preferred, in this embodiment, to use at least about 2 weight percent of water.

In another embodiment, an inert gas, such as argon, helium, nitrogen, CO₂, and the like, may be introduced into nozzle 103 as a means of regulating the temperature of the sheath 114. The percent volume of such as gas used should preferably be less than about 20 percent, and more preferably less than about 10 percent, although it is preferred to use at least 2 percent of such gas.

It is preferred that the sheath 114 contain ionized species of both hydrogen and hydroxyl moieties, such as, e.g., hydroxyl ion, hydrogen ion, and the like. It is preferred that, on balance, the sheath 114 present a reducing atmosphere. As is known to those skilled in the art, a reducing atmosphere is an atmosphere (such as, e.g., hydrogen) that readily provides electrons to a chemical reaction.

Regardless of the composition of the gas within the nozzle 103, when combusted it forms the flame sheath 114 that preferably completely surrounds the flame core 108.

In one preferred embodiment of the invention, and without wishing to be bound to any particular theory, applicant believes that the sheath 114 performs five functions. The first function is to provide a physical barrier between the reacting process gas and the atmosphere. The second function is to remove, through chemical etching, unwanted graphite deposited by the outer edge of the process gas combustion flame; this is achieved by means of previously described hydrogen and oxygen radicals. The third function is to preheat the substrate for the moving deposition head, as will be described later; this is achieved through the proper combination and combustion of hydrogen, oxygen, argon, and water. The fourth function is to help reduce the heat generated by the flame, by limiting the combustion of carbon monoxide, hydrogen, and unburned hydrocarbons upon contact with the ambient atmosphere 107. The fifth function is foster further diamond which may take place on the diamond directly under the sheath, the carbon source for this growth being the unburned carbon monoxide and hydrocarbons diffused outward from the core.

The reactions undergone within the core 108 produce several types of carbon, including graphite and diamond material. Without wishing to be bound to any particular theory, applicant believes that both the hydrogen ions and the hydroxyl ions preferentially etch the graphite form of carbon, forming carbon monoxide and carbon dioxide. However, these radical moieties are substantially less reactive with the diamond form of carbon. Thus, the presence of the hydrogen and the hydroxyl ions in the system preferentially encourages the removal of the undesired graphite and the accumulation of the desired form of carbon material.

In another embodiment, not shown, this preferential etching capability can be used to remove non-diamond forms of carbon from any environment in which it is not desired.

As will be apparent, the faster the hydroxyl ions and the hydrogen ions are generated, the faster they will etch away the graphite, and the faster this will encourage the formation of the preferred diamond species.

In one preferred embodiment, no more than about a stoichiometric amount of hydrogen and/or hydroxyl radicals should be formed so that only enough of such radicals are formed to etch away only the graphite form of carbon. This will vary, depending upon such factors as the reaction rates of the various reactions, including the reaction forming both graphite and diamond. The latter reaction rate will vary depending upon such factors as the stociometry of the reagents, the temperature, etc.

In one embodiment, the process of the invention is conducted at substantially higher pressure or super-atmospheric pressure. In general, the higher the pressure, the higher the reaction rate. In one embodiment, the process of this invention is conducted at a pressure of from about 10 to about 2,000 atmospheres.

One Preferred Apparatus of the Invention.

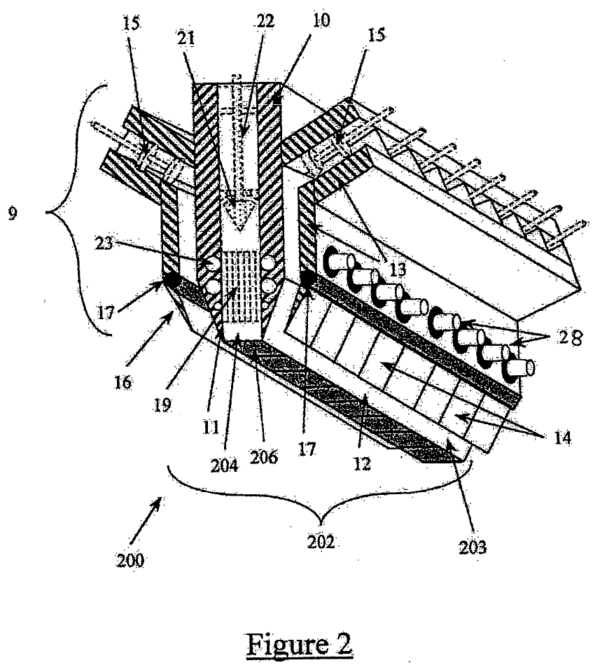

FIG. 2 illustrates a preferred apparatus 200 that is comprised of a series of torch units 9 placed together in linear fashion to comprise a deposition head 202. The sub-nozzles 204 of each torch unit 9 are preferably square in cross section rather than round, although other embodiments may use a rectangular cross-section.

Referring again to FIG. 2, it will be seen that each sub-nozzle 204 comprises an opening 206 with a maximum dimension of form about 3 to about 10 millimeters. In the embodiment depicted in FIG. 2, each such sub-nozzle 204 is comprised of four walls, each of which are relatively thin, having a thickness of less than about 0.5 millimeters at the gas exit point.

It is preferred that the assembly of sub-nozzles 204, and torch units 9, collectively create a single flame across the collective rectangular large nozzle 12. As will be apparent, the design depicted in FIG. 2 minimizes the turbulence that frequently occurs when circular nozzles are placed in close proximity to each other.

In the embodiment depicted in FIG. 2, a substantially rectilinear cross-section is shown for sub-nozzles 204, as with the nozzle openings 206. In other embodiments, not shown, one may use rectangular shapes.

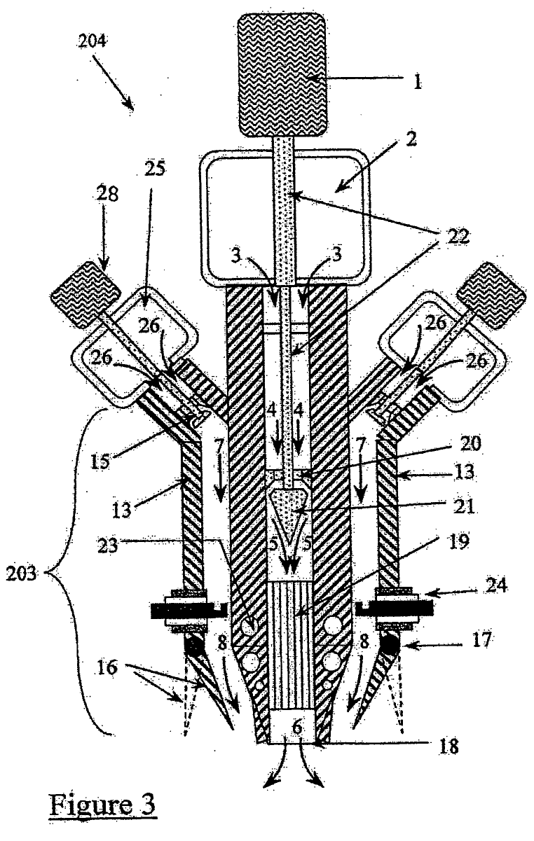

Referring again to FIG. 2, and also to FIG. 3, and in the preferred embodiment depicted therein, it is preferred that the body of each sub-nozzle 204 consist essentially of brass, bronze, or any other metal or metal-containing material that will not form a metal carbide in the presence of the reagents used in the instant process and at the specified temperatures. It is also preferred that the material so used not allow carbon to enter into a solid solution with the material used. Thus, by way of illustration, the sub-nozzles 204 may be constructed of bronze or brass.

Referring again to FIG. 2 and FIG. 3, and in the preferred embodiment depicted therein, it will be seen that cooling channels 23 are preferably disposed throughout each sub-nozzle 204 and preferably connect to the cooling channels 23 of adjacent sub-nozzles 204.

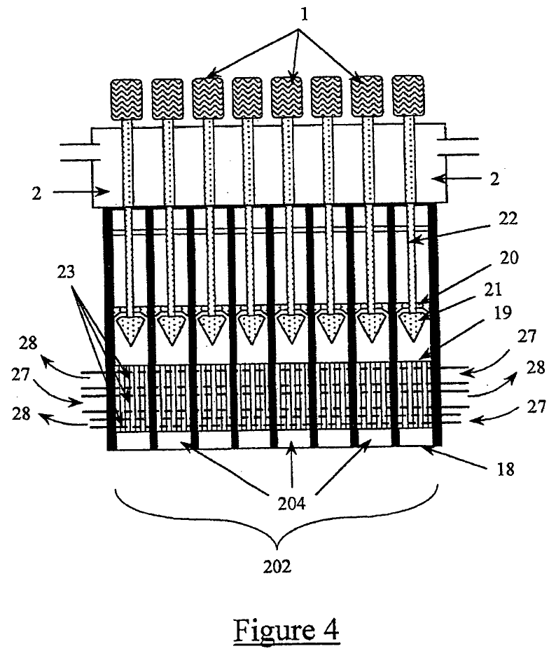

In the embodiment depicted in FIG. 4, the cooling channels 23 of the sub-nozzles 204 positioned on the end of the deposition head 202 are connected to the input lines 27 and the output lines 28 of a cooling unit (not shown). In one embodiment, a cooling fluid, such as glycerol or water, is used.

In another embodiment, a cooling gas such as argon, nitrogen, helium, and the like, is used.

Referring again to FIGS. 2 and 3, and in the preferred embodiments depicted therein, mounted on each side of the deposition head 202 is a series of sheath gas units 13 collectively forming a sheath gas nozzle 203. In the embodiment depicted, the sub-nozzles 14 of these sheath gas units are also rectangular in cross-section. Furthermore, it is preferred that the sheath gas units 13 consist essentially of metal-containing material such as, e.g., bronze, brass, etc., which are inert to reactions with carbon.

Referring again to FIGS. 2 and 3, and in the preferred embodiment depicted therein, each sheath gas unit 13 preferably contains a flow control valve 15 and a variable geometry sub-nozzle 16 with a hinged pivot point 17.

Referring again to FIG. 3, sub-nozzle 204 preferably contains a torch opening 18, a laminar conditioner 19, and a control valve connected to a measurement and feedback system to precisely control the size and temperature of the flame. The flow and control of the input gas mixture is achieved, in one embodiment, by means of a control valve system comprised of a valve actuator 1, a mixing manifold 2, a valve seat 20 and a low turbulence valve 21. The source gasses enter the manifold 2 where they are mixed before entering the nozzle 3. The design of the manifold is not specific to the invention, and any suitable manifold may be used provided that it meets the following requirements: (1) complete turbulent mixing, and (2) suppression of spontaneous combustion of the fuel and oxidizer. The gasses 4 proceed down the nozzle where they pass the control valve seat 20. The low turbulence control valve 21 is moved in reference to the valve seat by the valve actuator through a control shaft 22. In one embodiment the control valve may also serve as a flame arrestor for use with combustible gas mixtures. The gasses 5 flow past the control valve through a laminar conditioner 19, which serves to remove turbulence and force the gas into a state of laminar flow. In this embodiment the laminar conditioner is comprised of small ceramic tubes 0.5 mm in diameter. These tubes may be smaller than 0.5 millimeters diameter and made of any suitable material such as SiC, Al₂O₃, Si₃N₄, ZrO₂, TiO₂ or any other stable ceramic of sufficient strength and resistance to thermal decomposition. In a different embodiment, tubes could be made of tungsten, molybdenum, or any other refractory metal of sufficient strength, resistance to thermal decomposition. In another embodiment, alternative structures such as fins are used to produce a laminar conditioner. After passing through the laminar conditioner the gas mixture 6 exits the nozzle at the torch opening 18 where it is ignited to produce a flame.

Referring again to FIG. 2 and FIG. 3, the flow and control of the sheath gas mixture is achieved in the preferred embodiment by means of a valve control system comprised of a valve actuator 24, a mixing manifold 25, a flow control valve 15, and a variable geometry sub-nozzle 16. The sheath gasses enter the manifold 25 where they are mixed before entering the sheath gas unit 13. The gasses 26 proceed down the nozzle where they pass the flow control valve 15. In the preferred embodiment depicted, an automated valve actuator operates each sheath gas control valve. In another embodiment, the sheath gas control valve 15 is actuated manually. The sheath gas 7 then flows past an igniter 28 where any combustible gasses are ignited. It is preferred that the igniter 28 consists of a device generating a continuously pulsed electrical spark, such as a modified spark plug. In another embodiment, the igniter initiates combustion using a heated filament or glow plug. The ignited sheath gas 8 then flows through a variable geometry sub-nozzle 16 before exiting on either side of the process gas sub-nozzle. In the preferred embodiment, an automated actuator is used to position the variable geometry nozzles. In another embodiment, the variable geometry nozzles are operated manually.

A torch unit along with its two sheath gas units makes up a head sub-nozzle 204. These head sub-nozzles are standardized and modular, and a series of them can be connected together to produce a deposition head 202 of any length. This standardization and modularity greatly reduce the capital costs of producing large deposition machines and are unique features of this invention.

Properties of the Apparatus Used to Control the Deposition of Material

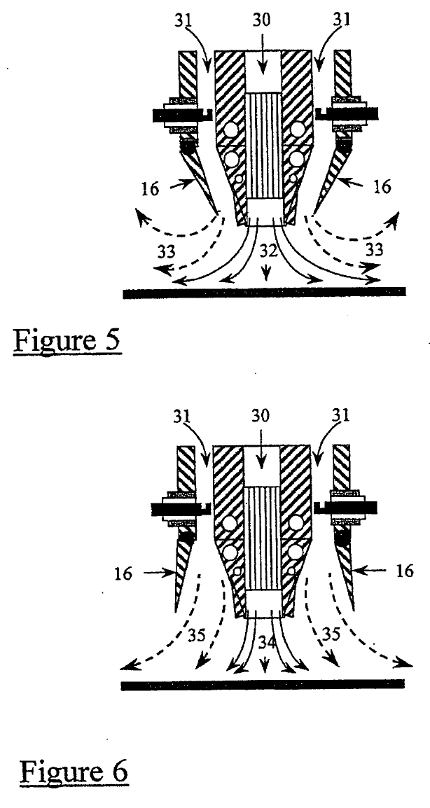

In addition to the manipulation of the process gas and sheath gas chemistries described above, reaction conditions can also be manipulated mechanically. Referring to FIG. 5, it will be seen that, by varying the process gas flow rate 30, the sheath gas flow rate 31, and variable geometry sub-nozzle 16, control of flame velocity and flame turbulence is achieved. With the sheath gas nozzle constricted, the sheath gas moves at high velocity from the nozzle 33. The low pressure of the high velocity stream allows the process gas stream 32 to undergo expansion, lowering its velocity and moving the process towards a “stagnation flow” or reaction-limited regime. Referring to FIG. 6, it will be seen that, by opening the sheath gas nozzle, the sheath gas undergoes expansion and lowers its velocity 35. The low velocity and increased pressure of the sheath gas stream causes the process gas stream 34 to constrict and move at high velocity, which moves the process towards a diffusion-limited regime. This aspect of the invention allows the pressure and flow rates of the process gas over the substrate to be varied by the mechanical manipulation of the sheath gas stream.

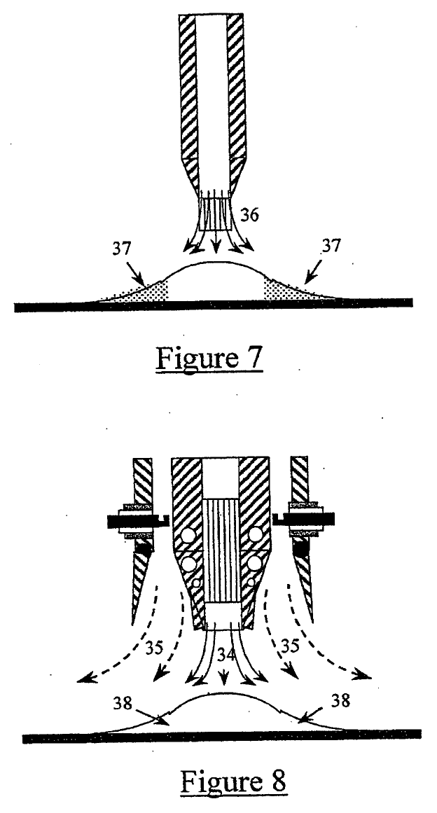

Referring to FIG. 7, it will be seen that a standard combustion torch deposition system leaves an annular region 37 outside of the center region deposited by the flame 36 which is generally of low quality and containing large amounts of impurities 38.

Referring to FIG. 8, by means, described earlier, of controlling the sheath gas pressure, chemistry, and temperature 35, and thus the characteristics of the process gas stream 34, the outer regions of the deposition remain free of graphite impurities 38.

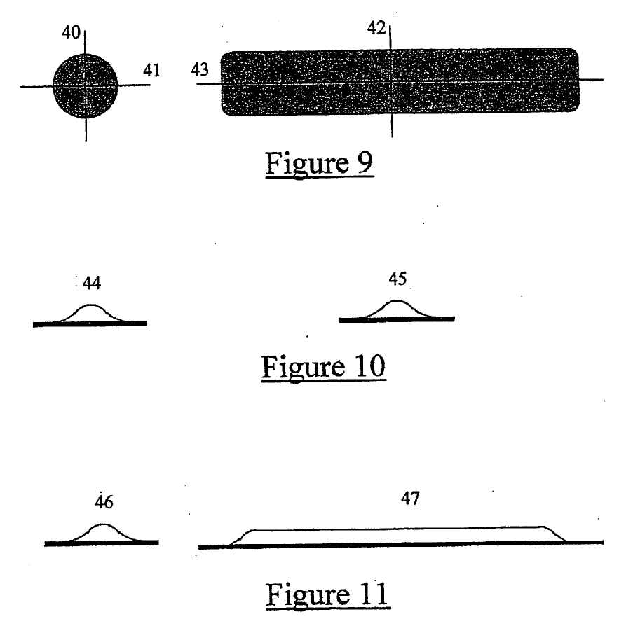

By controlling the deposition parameters across the length of the deposition head, a uniform rate and area of deposition is achieved across the length of the head. Instead of a small annular region of deposition created by a single round nozzle, a long rectangular region is created. Referring to FIG. 9, FIG. 10, and FIG. 11, the properties of the material deposited by a conventional combustion torch show a radial symmetry, whereas the properties of the material deposited by the invention show a linear symmetry, where the axis of symmetry is parallel to the long axis of the deposition head. Illustrated in FIG. 9 is a top view of deposited material from a conventional combustion torch on the left and that from the invention on the right. The lines 40 and 41 describe two perpendicular cross sections though the material deposited by a conventional combustion torch and the lines 42 and 43 describe two perpendicular cross sections though the material deposited by the invention.

FIG. 10 illustrates a side view 44 of the material deposited by a conventional combustion torch through the cross section 40. It also illustrates a side view 45 of the material deposited by the invention through the cross section 42.

FIG. 11 illustrates a side view 46 of the material deposited by a conventional combustion torch through the cross section 41. It also illustrates a side view 47 of the material deposited by the invention through the cross section 43. The vertical height of the deposited material in FIG. 10 and FIG. 11 is exaggerated for clarity.

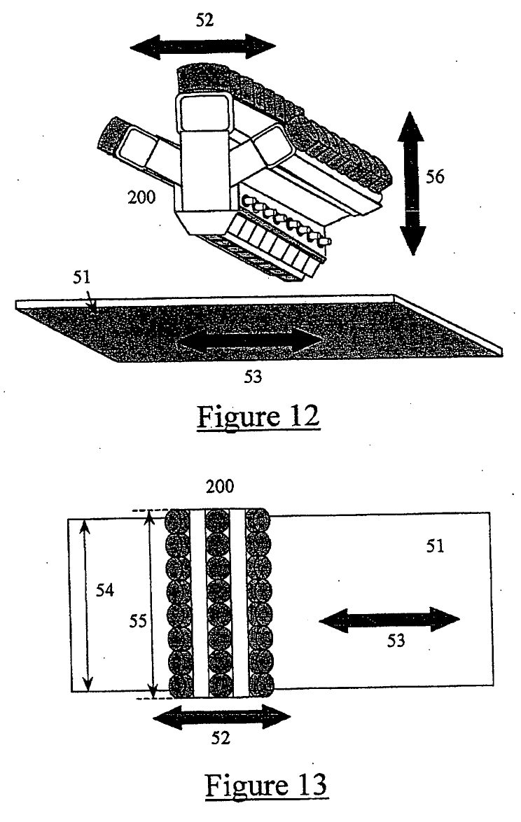

In one embodiment, as illustrated in FIG. 12 and FIG. 13, the deposition head 202 is connected to a movable frame above the stationary work-piece/deposition area 51. The deposition head 202 can then scan across the work-piece in a direction perpendicular to its long axis 52.

In a different embodiment, depicted in FIGS. 12 and 13, the work-piece/deposition area 51 is connected to a movable frame below a stationary deposition head 202. The work-piece/deposition area 51 can then scan below the deposition head 202 in a direction perpendicular to its long axis 53.

In another embodiment, depicted in FIGS. 12 and 13, the deposition head 202 and the work-piece/deposition area 51 are both movable.

In the preferred embodiment depicted in FIG. 13, the width 54 of the work-piece is no larger than the width 55 of the deposition head 202. The deposition head 202 then proceeds to scan across the length of the work-piece/deposition area 51 until the entire work-piece is coated. Multiple passes of the head are preferably used to obtain thicker coatings. Alternatively, or additionally, variations in the speed of the head may be used to control coating thickness.

The deposition head 202 also has the ability to move in the vertical direction 56 in order to place the flame at the proper height above the work-piece/deposition area 51.

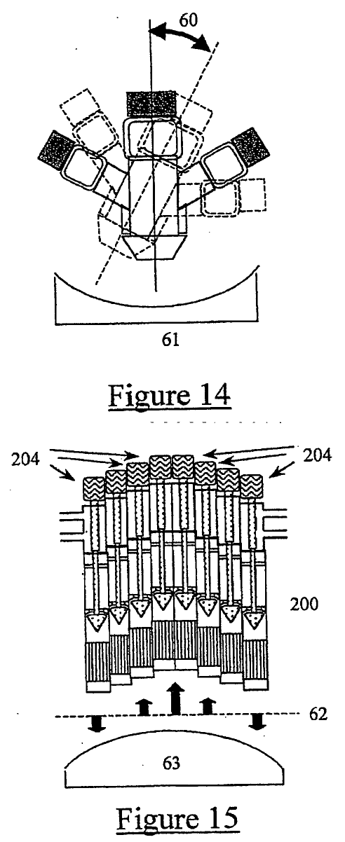

In another embodiment of the invention, depicted in FIG. 14, the deposition head 202 has the ability to be rotated along a horizontal axis 60 parallel to the line 43 depicted in FIG. 9. This allows it to deposit material over surfaces 61 that are not flat with respect to the line 42 depicted in FIG. 9.

In another embodiment of the invention, depicted in FIG. 15, the deposition head 202 comprises head sub-nozzles 204 that are adapted to move independently of each other in the vertical direction. Thus, in the embodiment depicted, the sub-nozzles 204 are not evenly aligned with line 62. This allows the deposition head 202 to deposit material over surfaces 63 that are not flat with respect to the line 43 depicted in FIG. 8.

Properties of the Apparatus Used to Control the Temperature of the Deposition

An aspect unique to this invention is the ability to control the substrate temperature, either partially or completely, through movement of the deposition head. As is known to those skilled in the art, chemical vapor deposition (CVD) of diamond occurs when substrate temperatures between 600° Centigrade and 1100° Centigrade are maintained. For most low-pressure CVD processes, the temperature is maintained through independent substrate heating. For atmospheric pressure processes, the temperature is maintained through active substrate cooling since atmospheric pressure processes deposit far more heat energy into the substrate than low-pressure CVD processes. Since the heat input into the substrate is directly related to the chemical reaction rate, and by inference the diamond growth rate, a substantial amount of energy is required to extract excess heat from the substrate in high growth rate systems. This situation is exacerbated when the substrate is composed of a material with a low coefficient of thermal conductivity.

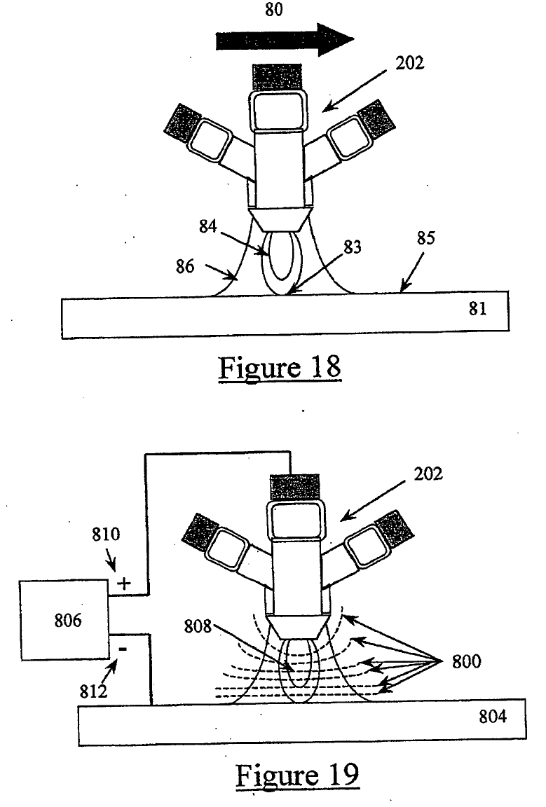

Referring to FIG. 18, in the preferred embodiment depicted therein, the velocity 80 of the deposition head 202 in relation to the substrate 81 is such that the area 83 directly under the deposition head 202 (which is also the area where the diamond deposition and growth takes place) remains within the previously stated optimal temperature range of from about 600 and about 1,100 degrees Centigrade.

In the embodiment depicted, a stationary flame 84 placed over a substrate 81 to input heat energy into the substrate. The temperature of the substrate will increase over time until thermal equilibrium is achieved. The rate at which this occurs depends on the specific heat of the substrate, the thermal conductivity of the substrate, the magnitude of the thermal mass, and the rate of heat loss from the system, all of which are subject to the appropriate heat flow equations. Depending on the rate of heat loss from the system, an area 83 located directly under the flame 84 will have a temperature lower than a point 85 on the substrate located a distance away from the flame. Thus, the temperature of a point on a substrate is directly related to the dwell time of the flame on that point; the longer the dwell time the higher the temperature, and the shorter the dwell time the lower the temperature. The dwell time can be described as the period of time that the flame resides over any given point on the substrate. From this it can be shown that a point on a substrate can be raised to any temperature T by adjusting the dwell time of the flame, within the limitations T_{R}<T<T_{M} where T_{R} is room temperature and T_{M} is the maximum temperature attainable by a stationary flame.

The temperature of any area 83 and point 85 on the substrate 81 can now be controlled by the velocity 80 of the deposition head 202, since the dwell time is directly dependent on the head velocity 80. In order to insure that the temperature of a given point on the substrate is at all times within the optimal temperature range while under the flame, a certain amount of preheating can be used. This preheating is accomplished by the sheath gas 86, which, containing a significant amount of hydrogen and oxygen, can be ignited. Thus, in addition to the etching of unwanted graphite, and the shielding of atmospheric contaminants, the sheath gas also can serve to regulate the temperature of the substrate.

Properties of the Apparatus Used to Control the Stress of the Deposited Material

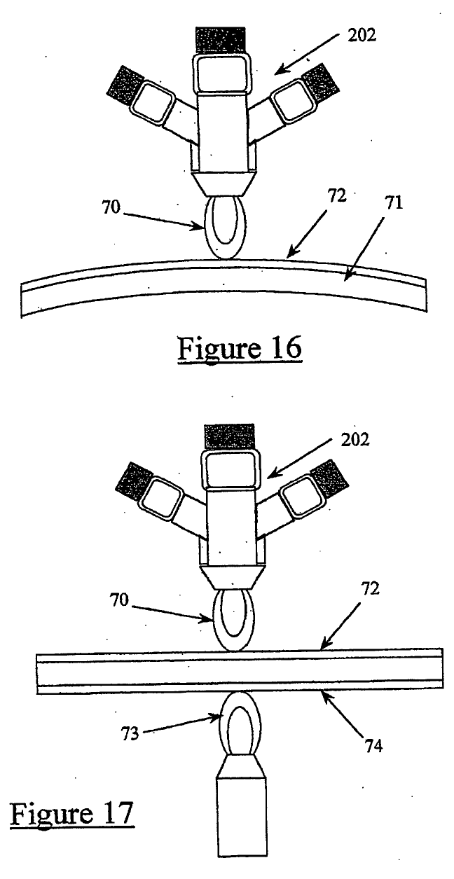

Referring to FIG. 16, in the case of diamond growth in a stationary high deposition rate system, a major disadvantage is that the entire surface of the top of substrate is subject to high thermal energy input by the flame 70. If the bottom of the substrate 71 is cooled or allowed to float thermally, there will be a temperature differential between the top and bottom of the substrate. This differential is needed to remove excess heat from the top of the substrate and keep it within the optimal temperature range for diamond growth. This temperature differential results in stress along the top substrate 72, which, if severe enough, can lead to warping of the substrate. If diamond is deposited on the warped substrate, the diamond will undergo compressive stress when the substrate returns to thermal equilibrium since the thermal expansion coefficient of diamond is less than that of any other material. Often this leads to the deposited diamond loosing adhesion or “peeling off” of the substrate.

Referring to FIG. 17, this invention allows one of a number of methods to be employed to avoid the problem of substrate warping. One method, illustrated in FIG. 17, is through the use of another flame 73 for example, to heat the bottom of substrate 74 to a temperature equal to or slightly greater than the temperature of the top of the substrate 72. This avoids warping by equalization of the top and bottom stresses, causing them to cancel each other out. The application of this technique has in the past been available to low deposition rate systems but not with high deposition rate systems since simultaneous heating at high rates from both sides of the substrate will quickly lead to temperatures above the range required for diamond growth.

In one embodiment of the invention, a unique solution is offered to this problem by allowing heating at high rates from both sides of the substrate without exceeding the temperatures required for diamond growth. Referring to FIG. 18, this is accomplished by the fact that the moving deposition head 202 only heats the substrate locally over a small area 83; this small area 83 is less than about 20 square centimeters. The remaining area of the substrate, such as that containing point 85, is allowed to cool and acts as a heat sink drawing excess heat from the area 83 under the flame. The same can be said for the addition of another heat source directly under the flame, providing heat input comparable to that of the flame. Though the total heat input of both heat sources is large enough to locally raise the temperature of the substrate into the range required for diamond growth, it is not enough to heat the entire substrate into this range. Thus by manipulation of the ratio of surface heating to bottom heating it is possible to control the thermal stress levels of the substrate, and further engineer these stress levels to minimize substrate warping and improve the adhesion of the diamond deposit.

Method and Apparatus for Plasma Enhancement

In one embodiment of the process of this invention, depicted in FIG. 19, the quantity of plasma within the flame is increased. As used herein, the term plasma refers to an electrically conductive ionized gas.

In one embodiment, illustrated in FIG. 19, an electric field 800 is established between the deposition head 202 and the substrate 804, preferably by means of a high voltage direct current power supply 806 operatively connected to said deposition head 202 and said substrate 804. In general, the power supply 806 provides a voltage of at least 1,000 volts. The dashed lines represent the electric potential lines. In one embodiment, the power supply 806 delivers pulsed direct current.

One may use other means of generating or enhancing plasma with a direct current. Thus, e.g., one may use the means disclosed in U.S. Pat. No. 6,222,321, the entire disclosure of which is hereby incorporated by reference into this specification. As is disclosed in such patent, “Plasma processing techniques have found wide-spread use in industry for commercial processes such as plasma vapor deposition, sputtering, etc. These processes have become particularly useful in thin film applications. To generate a plasma, a power supply creates an electric potential between a cathode and one or more anodes that are placed in a plasma chamber containing the gases that are used to form the plasma. When using these processes for deposition, the plasma acts upon the material of a target placed in the plasma chamber that normally comprises the cathode surface. Plasma ions cause target material to be dislodged from the cathode surface. The target materials are then deposited on a substrate deposition surface to form a thin film. The thin film may constitute material sputtered by the plasma from the target surface, as disclosed above, or may be the result of a reaction between the target material and some other element included in the plasma. The materials and elements involved, as well as the specific applications of the plasma processing techniques vary greatly. Applications may range from coating architectural glass to deposition of thin film layers on microchips, or deposition of aluminum layers on compact disks.”

“In the past, high frequency voltage sources have been used to generate a high electrical potential that produces a plasma within a plasma chamber. These high-frequency voltage sources are expensive to construct and maintain, as well as dangerous to operate. Additionally, if the deposition material is formed by reaction with an element in the plasma, and further, is electronically insulating, the anode in the chamber can be coated with the insulator; this deposit can then prevent the anode from performing its function of collecting the electrons released from the plasma during the deposition process.”

“To overcome these disadvantages, pulsed DC voltage sources have been employed such as disclosed in U.S. Pat. No. 5,303,139 issued Apr. 12, 1994 to Mark, which is specifically incorporated herein by reference for all that it discloses and teaches. Mark discloses a constant voltage pulsed power supply that has alternating pulse polarities. The advantages of such a constant voltage pulsed power supply over the AC power supplies are that they are less expensive, easier to connect and set up, and overcome the problem of coating the anode if used with two target units. That is, the process of reversing polarities allows the electrodes to alternately act as anode and cathode; the sputtering process that occurs during the cathode phase cleans off any deposited insulating material and permits uninhabited operation of the electrode as an anode during the anode phase. Additionally, the process of reversing polarities allows both electrodes to alternatively act as a cathode so that both electrode surfaces are capable of providing target material.”

Other conventional means of enhancing the plasma region within the flame 808 may also be used.

In one embodiment of the process of this invention, illustrated in FIG. 19, the field 800 is preferably disposed such that the deposition head 202 is biased positively 810 and the substrate 804 is biased negatively 812. The electric field should have a field strength such that a free electron disposed within such field has an energy of at least about 14 electron volts within its mean free path length. Without wishing to be bound to any particular theory, applicant believes that such a combination of conditions causes an “ion cascade” condition to occur.

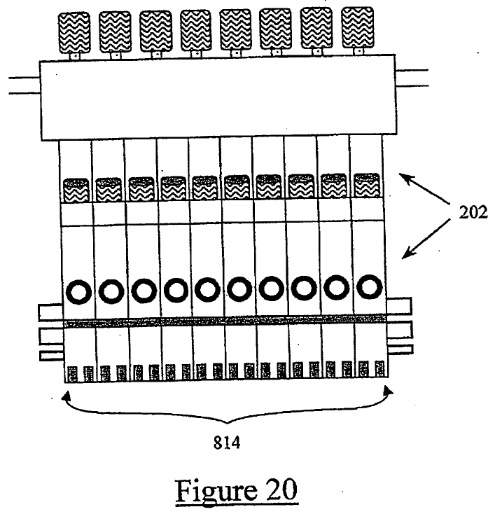

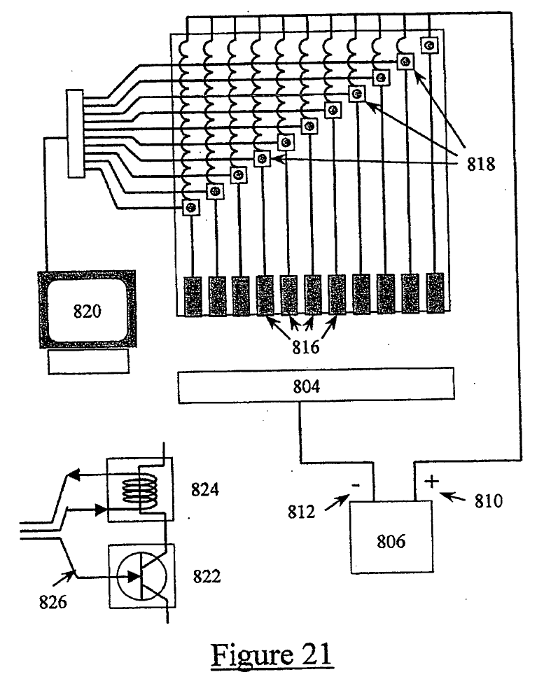

In another embodiment of the process of this invention, illustrated in FIG. 20, the charge on the deposition head 202 is distributed to the flame by means of an array of electrodes 814. These electrodes may be fabricated out of platinum, iridium, or any other metal capable of withstanding the high heat of the combustion flame while also resisting a chemical reaction to chemical components of the flame. The width and separation of these electrodes should be on the order of one to two millimeters. In order to prevent the discharge of all of the electrical current between any one single electrode 816 and the substrate 804, a scheme of current limitation is employed in a manner represented in FIG. 21. In this configuration, the positive current 810 flowing from the power supply 806 to the electrodes 816 on the head must first pass through a power regulator 818. The function of the power regulator is to monitor and limit the current available to its corresponding electrode 816. The power regulator 818 is composed primarily of two parts; a power transistor 822 which limits the electrical current by means of an applied voltage to the transistor gate 826, and a current monitor 824 which measures the current flowing to the electrode 816. The current monitor may be an induction-type device, as illustrated, but is not limited to electrical induction as a means of measuring current. Other methods, including resistive, magnetic, or solid state transistor, may also be used. The level of the transistor gate 826 on the power transistor 822, and hence the level of the current available to the electrode 816, is variable and may be monitored and controlled by a computer 820. Each electrode preferably has its own corresponding power regulator 818 which may be controlled independently of any other, and without wishing to be bound to any particular theory, applicant believes that such a configuration will promote uniform current flow across the width of the head between the positive and negative electrodes.

In one preferred embodiment, the difference of potential between the electrodes 816 and the substrate 804 is at least about 250 volts and, preferably, at least about 1,000 volts. In one embodiment, such difference of potential is from about 1,000 to about 10,000 volts. Such a difference of potential causes a current to flow between the electrodes 816 and substrate 804 that, in one embodiment, is at least about 10 milliamperes.

The following examples are presented to illustrate the claimed invention but are not to be deemed limitative thereof. Unless otherwise specified, all parts are by weight and all temperatures are in degrees Centigrade.

### A Composite Diamond with a Thin Film Deposited Thereon

In this section of the application, applicant will describe a composite diamond substrate comprised of a diamond substance with a thin film deposited thereon comprising an adhesion layer, diffusion barrier layer, thermal barrier layer, chemical reactivity barrier layer, oxidation-reduction barrier layer, or any combinations thereof.

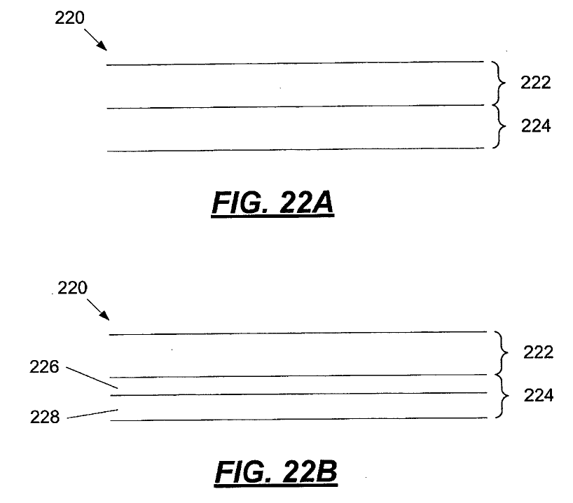

By way of illustration, but not limitation, and with reference to FIG. 22A, the composite diamond substrate 220 uses a gas-phase synthesized polycrystalline diamond substance 222. In one embodiment, said gas-phase synthesized polycrystalline diamond substance 222 is substantially free of chromium, aluminum, beryllium and titanium, all impurities found in natural diamond. In a preferred embodiment, said diamond is produced by the methods described elsewhere in this specification. As will be apparent to those skilled in the art, the purity of the gas-phase synthesized polycrystalline diamond substance 222 may be controlled by regulating the quality and purity of the source gas used during formation.

It is to be understood that the diamond substance 222 may be natural or synthetic and may be produced by any known method. It is to be further understood that said diamond substance 222 may be monocrystalline or polycrystalline. In some embodiments, the diamond may be a diamond containing substance.

In a preferred embodiment, the diamond substance 222 has diameter from 100 millimeters to 300 millimeters, a surface roughness that does not exceed 3 nanometers RMS, a flatness that does not exceed 2 microns per centimeter, a purity of less than 10 ppm, and a homogeneity of impurities of no more than 10%. Applicant believes that the homogeneity, shape and size of the diamond substance 222 meets the strict materials requirements necessary in the semi-conductor, optical and aerospace industries.

Synthetic diamond compositions produced by prior art methods have inherent application limitations due to their specific material properties. In particular, reactivity at the surface of the diamond with other materials (such as semiconductors) produces well-known defects and traps in the diamond material surface. The novel composite diamond substrate 220 of the present invention addresses these problems in the art by coating such diamond substance 222 with a thin film 224 comprising a barrier layer. Such a barrier layer is comprised of a diffusion barrier layer, thermal barrier layer, chemical reactivity barrier layer, oxidation-reduction barrier layer, or any combinations thereof. Preferably, such thin layer 224 provides all or as many of these barrier layer effects as needed. Additionally, in some embodiments, thin film 224 comprises an adhesion layer.

Adhesion—Issues in the Art

Adhesion to the diamond surfaces has been a long standing problem in the prior art, especially when attempting to adhere a semiconductor to the diamond material. Conventional processes include covalent bonding techniques on smooth surfaces activated with plasma (reference is made to U.S. Pat. No. 6,902,987 and “Semiconductor wafer bonding”, U. Gösele, Q.-Y. Tong, Annual Review of Materials Science, August 1998, Vol. 28, Pages 215-241), chemical bonding (reference is made to U.S. Pat. Nos. 6,087,009 and 5,116,568), solder bonding (reference is made to U.S. Pat. Nos. 6,427,901 and 5,340,016), and pressure bonding (reference is made to U.S. Pat. Nos. 6,135,345 and 4,875,616). The entire disclosure of each of these patents is hereby incorporated by reference into this specification. Pressure bonding and covalent bonding processes require extremely clean environments such as Class 100 clean rooms or better. Pressure bonding is a method by which two separate materials are bonded through the application of high pressure between the materials. Often this is accompanied by high temperatures. Pressure bonds are not possible between all materials as their surfaces must be amenable to bonding with each other. Pressure bonding also may add high levels of defects to the surfaces. Covalent bonding requires extremely smooth surfaces with a surface roughness usually less than 5 Angstroms RMS. For many hard materials including diamond, it may be impossible or impractical to achieve the required smoothness. Chemical bonding requires the use the application of a reactive material between the two surfaces to be bonded. Once the surfaces make contact, heat or another activation method is used to initiate a chemical reaction between the reaction layer and each of the two surfaces. The resulting chemical reactions form new compounds between the materials. Use of chemical bonding is limited since the material in the reaction layer must form stable compounds with the materials of both surfaces. Solder bonding is a very common form of bonding. It can also be used to bond ceramics to ceramics or ceramics to semiconductors. However, reliable solder bonds have not been made for surfaces with areas over 100 square centimeters. Solder bond are also very thick compared to other bonding techniques, often exceeding 50 microns in thickness. Additionally, the solder bonding of ceramics and semiconductors requires that both pieces have metalized surfaces. The metallization of ceramic or semiconductor surfaces may often be impractical or impose unreasonable costs.

Without wishing to be bound to any particular theory, applicant believes that bonding problems are at least partially attributable to thermal expansion coefficient mismatching. By way of demonstration, when the diamond adjoins and directly contacts ceramic materials having a different thermal expansion coefficient, there is a tendency to cause delamination, warping, peeling, cracking, and blistering. When the diamond adjoins and directly contacts metallic and metallic alloy materials having a different thermal expansion coefficient, there is a tendency to bend and delaminate. A metalized diamond film can be solder bonded to a metalized gallium arsenide die of one square centimeter area using a silicon-tin eutectic solder. The melting point of the solder is 420° C. Upon the solder melting the diamond film and gallium arsenide die are put in contact. When the temperature begins to drop and the solder solidifies the bond has been made. However, once the bonded diamond film and gallium arsenide die reach room temperature, delamination, warping, peeling, cracking, and blistering can be observed visually or using a low power optical microscope.

Adhesion Layer and Barrier Layer

In one embodiment of the present invention, illustrated in FIG. 22B, the barrier layer 224 of diamond substrate 220 is comprised of adhesion layer 226 and barrier layer 228. In the embodiment depicted in FIG. 22B, the adhesion layer 226 is contiguous with diamond substance 222 and adheres firmly to the surface thereof. In one embodiment, a peel force analogous to an adhesion strength value of at least 50% of the tensile strength value of the barrier layer is required to remove the barrier layer 224 from the diamond substance 222. In another embodiment, a peel force analogous to an adhesion strength value greater than the tensile strength value of the either the barrier layer 224 or the diamond substance 222 is required to affect such a removal. In some embodiments of the present invention, more than one adhesion layer 226 is employed.

Suitable methods for measuring peel forces are known to those skilled the art. Reference may be had to U.S. Pat. No. 5,103,678 to Covino-Hrbacek (Fiber Peel Force Measuring Apparatus), the contents of which are hereby incorporated by reference into this specification.

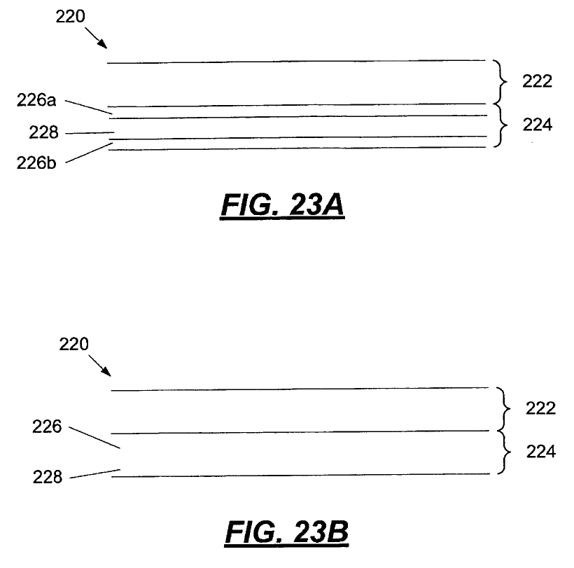

FIG. 23A illustrates one embodiment, wherein two such adhesion layers 226 are employed. In the embodiment depicted, barrier layer 228 is disposed between, and contiguous with, a first adhesion layer 226a and a second adhesion layer 226b. In another embodiment, not shown, more than one barrier layer is used, with adhesion layers disposed between at least some of the layers. In another embodiment, a layer is used that possesses properties of both the adhesion layer and the barrier layer.

FIG. 23B depicts another embodiment of the present invention wherein thin film 224 is comprised of a single layer which has the properties of both adhesion layer 226 and the properties of barrier layer 228. A variety of suitable barrier layers may be used in the thin film.

The Thin Film

In one embodiment, and with reference to FIG. 22A, thin film 222 has a thickness of from about 10 to about 100,000 angstroms, preferably from about 10 to about 5,000 angstroms, more preferably less than about 1 micron, and comprises at least one sub-layer. In other embodiments, said thin film layer comprises from about two to about ten sub-layers, preferably from about two to about five layers. Since each sub-layer inherently acts as a thermal barrier, applicant believes it is preferable, in some embodiments, to provide the desired effects with the thinnest and least number of layers practicable, striving for a thin film coating of less than about 10 microns.

However, applicant notes that some thermal expansion coefficient mismatches require a greater thin film coating thickness or more coated layers to absorb the stress differences as described elsewhere in this specification. By way of illustration, but not limitation, said stress differences may include expansion mismatch stress, lattice mismatch stress, thermal stress, or stress acquired during the thin film coating process. In some embodiments, thermal expansion coefficient mismatches are treated with a thin layer coating comprising a gradient of expansion coefficients. In a preferable embodiment, such a gradient comprises materials with expansion coefficients between the diamond material and the adjoining material (such as, for example, a semi-conductor).

The novel composite diamond substrate of the present invention addresses these problems in the art by coating such diamond with a thin film adhesion layer. Said adhesion layer enhances bonding and minimizes stresses along the boundary between the diamond and the semiconductor. This is carried out primarily by choosing a thin film with a thermal expansion coefficient midway between that of diamond and the semiconductor. It is further carried out by using a bonding technique which can be applied at low temperatures.

It is to be understood that the examples provided refer to semi-conductors, but that other materials may be substituted as desired for the particular application. As such, semi-conductor references shall not be limiting, rather only exemplary.

Without wishing to be bound to any particular theory, applicant believes that problems with the use of bonded diamond are at least partially attributable to the chemical interaction at the surface of the diamond. By way of demonstration, when the diamond adjoins and directly contacts silicon at temperatures as low as 300 degrees Celsius (and even lower) under high electric fields, chemical interaction creates a silicon carbide layer. This silicon carbide layer is an undesirable secondary reaction zone that may interfere with the functionality of the respective materials. Applicant believes that this may contribute to defects and traps in the surface of the diamond.

As used in this specification, a secondary reaction zone that is deleterious to the mechanical properties of diamond means one where the resulting compound formed has a mechanical strength significantly less that that of the diamond or the adjoining material, a thermal expansion coefficient value outside of the range bounded by the diamond and adjoining material, or through its formation, induces a mechanical stress between the diamond and adjoining material, and may be measured qualitatively by changes in the local electron or x-ray diffraction characteristics.

As used in the specification, defects or traps means any structural or chemical defect that may cause adverse electrical properties such as leakage, variance in turn on-turn-off voltages, and decreasing or ceasing of transistor functions. These are not limited to but may include, for example, defects caused by lattice dislocations, impurities, lattice mismatches, and/or non-terminated bonds capable of capturing charged species.

Without wishing to be bound to any particular theory, applicant believes that such silicon carbide layer creates structural density differences in that the silicon carbide has a different lattice constant and unit cell than either the diamond or the silicon. As will be apparent to those skilled in the art, this creates tension and compression, leading to the delamination, cracking, warping and the like observed in many applications.

Applicant notes that not all chemical interaction is undesirable. Chemical interaction that does not create defects or traps may be benign. For example, nickel will interact with diamond to form nickel carbide. Certain stociometries of nickel and carbon form carbide with nearly the same lattice constant as diamond, and therefore may not create defects and traps.

Without wishing to be bound to any particular theory, applicant believes that the bonding problems are at least partially attributable to diffusion of species across the surface of the adjoining materials. By way of demonstration, when the diamond adjoins and directly contacts a semi-conductor, free carbon, boron and metals in the diamond material may diffuse into and poison the semi-conductor, adversely affecting its performance.

By way of further demonstration, dopant diffusion may be problematic. If for example, phosphorus is used as a dopant in the diamond synthesis process, and phosphine gas is created during processing by exposure of the diamond to a reactive hydrogen atmosphere, such phosphine gas may diffuse into and dope the semi-conductor, adversely affecting its performance. It is well known to those in the art, that high-purity, non-reactive materials such as sapphire are used as wafer carriers during semiconductor processing. This is done to prevent impurities from being volatilized by the reactions occurring during the semiconductor process, where they may become incorporated into the semiconductor.

Without wishing to be bound to any particular theory, applicant believes that the bonding problems of diamond are at least partially attributable to “H-etching,” that is, oxidation and reduction reactions at the surface of the diamond material. It is well known that upon heating diamond beyond 700° C. in an oxygen containing atmosphere, oxidation of the surface will take place. This oxidation reaction converts the surface carbon from its sp3-bonded diamond form to its sp2-bonded graphite form. This graphite-forming reaction may continue as long as oxygen is resent until the entire diamond substance has been converted to graphite. It is well known that upon heating graphite beyond 500° C. in a steam containing atmosphere, oxidation and reduction the surface will take place. Diamond placed in a steam containing atmosphere at temperatures beyond 700° C. experience oxidation and reduction reaction of diamond and graphite resulting in the formation of CO₂ (oxidation) and methane (reduction).

General Barrier Layer

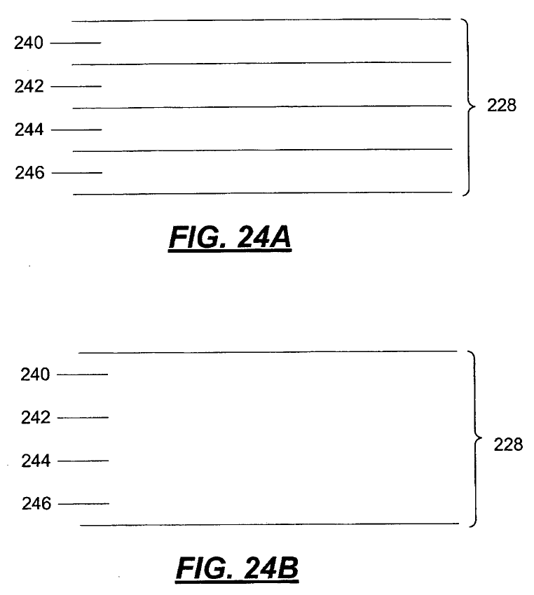

FIG. 24A shows one embodiment of barrier layer 228. In the embodiment depicted, barrier layer 228 is comprised of four sub-layers; diffusion barrier layer 240, thermal barrier layer 242, chemical reactivity barrier layer 244 and oxidation-reduction barrier layer 246. In another embodiment, not shown, barrier layer 228 is comprised of at least one layer selected from the group consisting of a diffusion barrier layer, a thermal barrier layer, a chemical reactivity barrier layer, an oxidation-reduction barrier layer, and combinations thereof. As would be apparent to one skilled in the art, the relative order of the layers is not critical. A variety of ordering configurations may be used and are considered to be within the scope of this invention. In one embodiment, the barrier layer 228 is a single layer that possesses properties of at least two of the aforementioned sub-layers. Such an embodiment is illustrated in FIG. 24B.

Each of these sub-layers and the respective sub-layer property will be discussed individually. However, as discussed elsewhere in this specification, such sub-layers may be used in combination with one another, and thus, a certain synergy may exist when certain sub-layer combinations are used.

Diffusion Barrier Layer

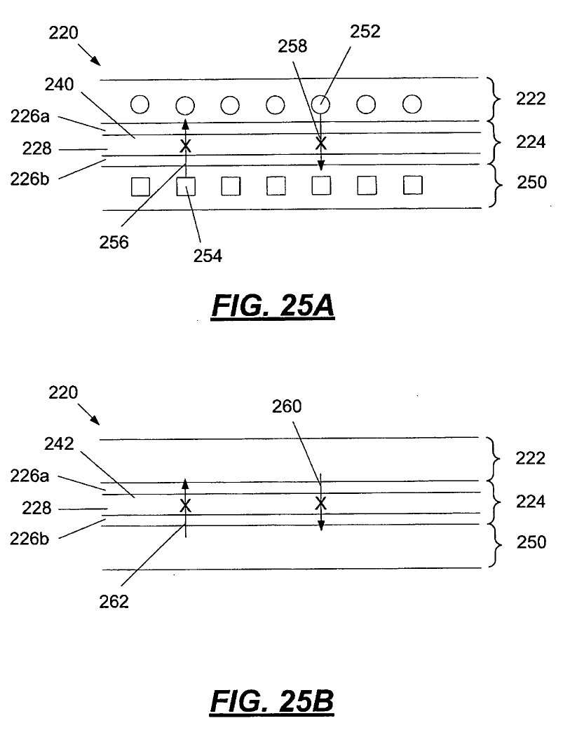

FIG. 25A is an illustration of the use of diffusion barrier layer 240. In the embodiment depicted, diamond substrate 220 is comprised of diamond substance 222 and thin layer 224. In the embodiment illustrated, thin layer 224 is contiguous with the surface of target material 250. Thin layer 224 is comprised of first adhesion layer 226a that adheres to diamond substance 222, second adhesion layer 226b that adheres to target material 250, and barrier layer 228. Barrier layer 228 is comprised of diffusion barrier layer 240, although additional barrier sub-layers may be used. In the embodiment illustrated in FIG. 25A, diamond substance 222 is comprised of first atoms 252. In one such embodiment, first atoms 252 are carbon atoms. In one embodiment, target material 250 is comprised of second atoms 254. In one such embodiment, target material 250 is a semi-conductor and second atoms 254 are silicon atoms. Diffusion barrier layer 240 prevents the diffusion of first atoms 252 across diffusion barrier 240 in the direction of arrow 258 and into target material 250. Likewise, diffusion barrier layer 240 prevents the diffusion of second atoms 254 across diffusion barrier 240 in the direction of arrow 256 and into diamond substance 222. The diffusion of such atoms into neighboring layers may be detrimental to the proper functioning of such layers. For example, when the target material 250 is a silicon semi-conductor, the diffusion of carbon from the diamond substance 222 into the target material 250 will disrupt the properties of the semi-conductor. Suitable tests for the measurement of such diffusion are well known to those skilled in the art. For example, one may use Electron Emission-Loss Spectroscopy (EELS) and/or Transmission Electron Microscopy (TEM) to measure the concentration of first atoms 252 and second atoms 254 in a given layer. Reference may be had to U.S. Pat. No. 6,541,374 to de Felipe (Method of depositing a diffusion barrier for copper interconnection applications); U.S. Pat. No. 6,254,984 to Iyori (Members with multi-layer coatings), and the like. The content of each of the aforementioned patents is hereby incorporated by reference into this specification. The diffusion barrier layer 240 has a diffusion coefficient of less than about 0.1, and more preferably less than about 0.05, and even more preferably less than about 0.01. The diffusion coefficient is measured using the following procedure; the diamond substrate 222 is coated with the thin film 224 which is comprised of diffusion barrier layer 240. The diamond substrate 222 is comprised of first atoms 252. The target material 250 is disposed above thin film 224. Target material 250 has a first concentration of first atoms 252. In one embodiment, this first concentration is zero. The resulting diamond substrate 220 is heated to a temperature of 800° C. for 10 hours within a hydrogen atmosphere. The substrate 220 is cooled to ambient temperature and the target material 250 is separated from thin layer 224. The target material now has a second concentration of first atoms 252. The diffusion coefficient is calculated as follows:

$$Diffusion Coefficient = \frac{second concentration - first concentration}{first concentration}$$

If the second concentration of first atoms 252 is zero, then the diffusion coefficient is said to be zero. It should be noted that such diffusion processes do not directly give rise to new chemical species; i.e. the first atoms 252 and second atoms 254 do not undergo a chemical reaction. In this manner, the diffusion barrier layer 240 discussed above may be distinguished from the chemical reactivity barrier layer 244 discussed elsewhere in this specification.

The diffusion of species is not limited to those atoms comprising the diamond and the second substance. Any atoms including those of dopants and impurities within the diamond substrate or the second substrate may be subject to diffusion, provided the concentration of that species in one substrate is different from that in the other substrate, thereby setting up a diffusion gradient.

Thermal Barrier Layer

As used in this specification, a thermal barrier layer is a layer that functions to increase or decrease the distribution of heat, or that functions to protect the diamond substance or target material as described elsewhere in this specification from temperatures over about 600 degrees Celsius. One such thermal barrier layer 242 is illustrated in FIG. 25B.

As shown in FIG. 25B, diamond substrate 220 is comprised of diamond substance 222, thin layer 224, and target material 250. Thin layer 224, in turn, is comprised of first adhesion layer 226a, second adhesion layer 226b, and barrier layer 228. In the embodiment depicted, barrier layer 228 is comprised of thermal barrier layer 242. The thermal barrier layer 242 increases or decreases the flow of heat from target material 250. Methods for measuring the thermal conductivity of such barriers are well known in the art. Reference may be had to U.S. Pat. No. 4,928,254 to Knudsen (Laser Flash Thermal Conductivity Apparatus and Method); U.S. Pat. No. 5,343,938 to Schmidt (Method and Apparatus for Thermally Insulating a wafer support); U.S. Pat. No. 5,652,044 to Rickerby (Coated Article); U.S. Pat. No. 5,846,605 to Rickerby (Coated Article); U.S. Pat. No. 5,912,087 Jackson (Graded bond coat for a thermal barrier coating system); U.S. Pat. No. 6,001,492 to Jackson (Graded bond coat for a thermal barrier coating system), and the like. The content of each of the aforementioned patents is hereby incorporated by reference into this specification.

Chemical Reactivity Barrier Layer

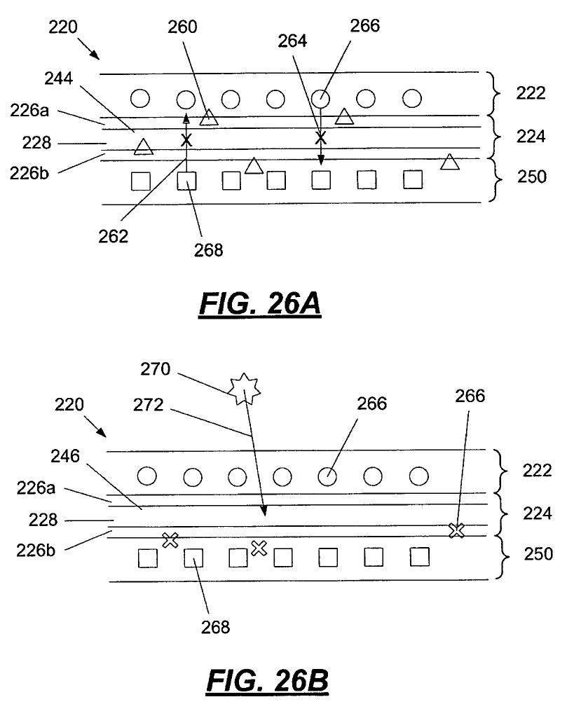

In addition to the diffusion barrier layer and the thermal barrier layer, the present invention also contemplates the use of a chemical reactivity barrier layer. As used in this specification, and with reference to FIG. 26A, the chemical reactivity barrier layer 244 is a barrier layer that inhibits a chemical reaction between reactant molecules 266 within the diamond substance 222 and reactant molecules 268 within target material 250, or the a barrier layer that inhibits a chemical reaction between reactant molecules 266 within the diamond substance 222 and reactant molecules 268 of any gas or liquid in contact with the diamond substance. Chemical product molecules 260 are the product of a chemical reaction between reactant molecules 266 and reactant molecules 268. Chemical product molecules 260 are the product of a chemical reaction between reactant molecules 266 and reactant molecules 268. For example, when the target material 250 is a silicon semi-conductor and the reactant molecules 268 are silicon containing molecules and when the reactant molecules 266 are carbon containing molecules of diamond substance 222, then the product molecules 260 are silicon carbide molecules. Chemical reaction products are distinguished from simple diffusion processes due to the formation of a new chemical species. In the previous example, the newly formed chemical species was silicon carbide. In another example, when the target material is a diamond substance 222 and the reactant molecules 226 are carbon containing molecules of the diamond substance, and when the reactant molecules 268 are oxygen containing molecules of a gas 250, then the product molecules 260 are carbon monoxide or carbon dioxide molecules. Chemical reactivity barriers may be measured by any method that can detect the concentration of the product molecules 260. For example, one may use Electron Emission-Loss Spectroscopy (EELS) and/or Transmission Electron Microscopy (TEM). In the case of the product molecules 260 being a gas, Time Of Flight Mass Spectrometry (TOFMS) or gas chromatography may be used. Reference may be had to U.S. Pat. No. 6,541,374 to de Felipe (Method of depositing a diffusion barrier for copper interconnection applications); U.S. Pat. No. 6,254,984 to Iyori (Members with multi-layer coatings), and the like. The content of each of the aforementioned patents is hereby incorporated by reference into this specification. Using such techniques, a chemical suppression coefficient may be determined.

To determine such a chemical suppression coefficient the diamond substrate 222 is coated with the thin film 224 which is comprised of chemical reactivity barrier layer 244. The target material 250 is disposed above thin film 224. Target material 250 has a first concentration of product molecules 260. In one embodiment, this first concentration is zero. The resulting diamond substrate 220 is heated to a temperature of 600° C. for 10 hours. The substrate 220 is cooled to ambient temperature and the target material 250 is separated from thin layer 224. The target material now has a second concentration of product molecules 260. The chemical suppression coefficient is calculated as follows:

$$Chemical Supression Coefficient = \frac{\begin{matrix}second concentration of product - \\ first concentration of product\end{matrix}}{first concentration of product}$$

The chemical reactivity barrier layer 244 has a chemical suppression coefficient of less than about 0.1, and more preferably less than about 0.05, and even more preferably less than about 0.01. If the second concentration of product molecules 260 is zero, then the chemical suppression coefficient is said to be zero.

Oxidation-Reduction Barrier Layer

In some embodiments, the present invention uses an oxidation-reduction barrier layer. As used in this specification, an oxidation-reduction barrier layer is a layer that blocks electron transfer compounds from diffusing therethrough. Suitable oxidation-reduction barriers are known to those skilled in the art. Reference may be had to U.S. Pat. No. 6,784,100 to Oh (Capacitor with Oxidation Barrier layer and method for manufacturing the same); U.S. Pat. No. 6,459,713 to Jewell (Conductive element with lateral oxidation barrier); U.S. Pat. No. 6,063,692 to Lee (Oxidation barrier composed of a silicide alloy for a thin film and method of construction); U.S. Pat. No. 6,737,120 to Golecki (Oxidation-protective coatings for carbon-carbon components); and the like. The content of each of the aforementioned patents is hereby incorporated by reference into this specification.

One embodiment of the present invention that uses such an oxidation-reduction barrier layer is illustrated in FIG. 26B. FIG. 26B depicts diamond substrate 220 which is comprised of diamond substance 222, thin film 224, and target material 250. Thin film 224 is comprised of first adhesive layer 226a, second adhesive layer 226b, and barrier layer 228. In the embodiment depicted, barrier layer 228 is comprised of oxidation-reduction barrier layer 246. Diamond substance 222 is comprised of first atoms 266, while target material 250 is comprised of second atoms 268. Disposed external to diamond substrate 220 is electron transfer molecule 270. In one embodiment, electron transfer molecule 270 is molecular oxygen. In another embodiment, electron transfer molecule 270 is molecular hydrogen. The electron transfer molecule 270 diffuses from the environment, in the direction of arrow 272, though oxidation-reduction barrier layer 246. Oxidation-reduction barrier layer 246 reduces the amount of such diffusion that occurs. When electron transfer molecule 270 contacts second atoms 268, an electron transfer reaction occurs and a new chemical species 266 is produced. The elemental composition of new chemical species 266 contains second atoms 268 and well as atoms from electron transfer molecule 270. In one embodiment, wherein target material 250 is comprised of silicon atoms and electron transfer molecule 270 is molecular oxygen, chemical species 266 is a silicon oxide. Such a chemical species 266 is distinguished from the product molecules 260 shown in FIG. 26A by their elemental composition. Product molecules 260 are comprised of first atoms 266 from diamond substance 222 and from second atoms 268 from target material 250. In contrast, chemical species 266 is comprised of second atoms 268 from target material 250 and from atoms from electron transfer molecule 270, which was delivered from outside diamond substrate 220. The concentration of chemical species 266 may be determined by techniques discussed elsewhere in this specification. An electron transfer coefficient can be determined in accordance with the following procedure: To determine such a coefficient the diamond substrate 222 is coated with the thin film 224 which is comprised of oxidation-reduction barrier layer 246. The target material 250 is disposed above thin film 224. Target material 250 has a first concentration of chemical species 266. In one embodiment, this first concentration is zero. The resulting diamond substrate 220 is heated to a temperature of 600° C. for 10 hours in an atmosphere that consists essentially of electron transfer molecules. The substrate 220 is cooled to ambient temperature and the target material 250 is separated from thin layer 224. The target material now has a second concentration of chemical species 266. The electron transfer coefficient is calculated as follows:

$$Electron Transfer Coefficient = \frac{\begin{matrix}second concentration of species - \\ first concentration of species\end{matrix}}{first concentration of species}$$

The oxidation-reduction barrier layer 246 has a electron transfer coefficient of less than about 0.1, and more preferably less than about 0.05, and even more preferably less than about 0.01. If the second concentration of chemical species 266 is zero, then the coefficient is said to be zero.

Applications

The composite diamond substrate produced by this novel process has particular advantages for the semi-conductor industry where there is a need for uniform, low-cost, large substrates that may be used as heat spreaders to remove heat from semiconductors, and/or a substrate intended to mechanically support a semiconductor layer. Diamond has a thermal conductivity substantially greater than all known semiconductor materials. For example, bulk silicon has a thermal conductivity at room temperature of 148 Watts per meter per degree Kelvin, whereas high quality bulk diamond has a thermal conductivity at room temperature in excess of 2000 Watts per meter per degree Kelvin. Replacement of all or a portion of the silicon material with diamond material increases the rate at which heat can be removed from the semiconductor.

The composite diamond substrate also has particular advantages for the optical industry where there is a need for high temperature broadband optical windows for high powered lasers. Although windows are assumed perfectly transparent, a small portion of the light is absorbed by the window material. When the window is used with high powered lasers, the optical power is so great that the light which is absorbed by the window, although small in proportion to the transmitted light, is of such a magnitude that the window material begins to heat. If the temperature of the window material exceeds some critical level, the window will melt or fail mechanically. The high thermal conductivity of diamond allows this heat to be easily removed, allowing higher intensity light to be transmitted, with the power of absorbed light being a fixed fraction of the total optical power.

The composite diamond substrate also has particular advantages for the military industry where there is a need for low temperature broadband infrared and sensor windows for hypersonic vehicles. Vehicles traveling at hypersonic velocities encounter substantial frictional resistance with the air which generates high levels of heat at the vehicle surface. Infrared and thermal sensors require windows to collect the radiation of interest. If allowed to become hot due to air friction, the windows themselves will generate thermal radiation. The thermal radiation generated by the window may exceed that received from the outside, thus blinding the IR or thermal sensor. The high thermal conductivity of diamond allows this heat to be easily removed, allowing the window to stay cooler during hypersonic flight.

The composite diamond substrate also has particular advantages for the aerospace industry where there is a need for lightweight materials with a high specific strength. For example, a carbon fiber or mesh grid composite within a diamond substrate by this novel process offers a material of superior strength. Fibers composed of carbon have exceedingly high strengths and strength-to-weight ratios. These fibers are used throughout the aerospace industry for use in structural composites and components. One composite material that exhibits superior properties is comprised of carbon fibers within a graphite matrix. These types of composites are known within the industry as carbon-carbon composites. Another carbon-carbon composite is comprised of carbon fibers within a diamond matrix. Since diamond has the highest modulus of all known materials, and has the highest thermal conductivity of all known materials, composites composed of carbon fiber and diamond would have mechanical and thermal properties superior to those composed of carbon fiber and graphite.

The composite diamond substrate also has particular advantages for the cutting tool industry where there is a need for a diamond material with a longer functional lifespan. The diamond material produced by this novel Chemical Vapor Deposition (CVD) process is superior to that termed “Poly Crystalline Diamond” (PCD) by those in the industry, producing a diamond material with up to 20 times the useable life of the product in cutting tool applications. Without wishing to be bound to any particular theory, applicant believes that the utilization of a binder in PCD processes contributes to material failure and thus, the absence of a binder contributes to the longer life of the diamond material produced by his novel process. Diamond is the hardest known substance, and the binder, being composed of non-diamond materials, cannot therefore have the hardness of diamond. Thus during use, wear on the binder exceeds wear on the diamond, and the binder fails before the diamond. Although the diamond component of the tool may still have a useful life, failure of the binder results in the failure of the entire tool.

The composite diamond substrate also has particular advantages for the electrochemical industry where there is a need for electrodes that are suitable for use in chemically or thermally corrosive environments. Diamond suitably doped with boron exhibits semiconductor properties such as the ability to conduct an electric current. Although electrically conductive, the diamond still exhibits a high resistance to chemical corrosion not shown by most metals. By way of further demonstration, such applications may include wastewater treatment, metal separation, and generation of ozone, generation of chlorine, chrome plating, or other electrochemical plating processes.

The composite diamond substrate also has particular advantages for the machinery and automotive industries where there is a need for materials with superior wear properties that are suitable for use in environmentally, chemically or thermally corrosive environments. Diamond has the lowest friction coefficient of any known substance including Teflon™, and therefore could potentially be used as a bearing material or wear plate where the surfaces of moving parts make contact. Bearings and wear surfaces composed of diamond are part of a class known as ceramic bearings. The high thermal conductivity of diamond allows heat generated by friction to be rapidly removed, thus allowing the cooler operation of components. The high hardness of diamond reduces wear and allows bearing components to last longer. The high corrosion resistance of diamond allows bearings and wear surfaces to function reliably in corrosive environments.

### Preparation of Thin Film and Composition Thereof

In this section of the application, applicant will describe the thin films used in the novel diamond substrate with thin film deposited thereon and novel diamond substrates described in this specification. In a preferred embodiment, a thin film will have all of the desired properties described above, that is, adhesion, diffusion barrier, thermal barrier, chemical reactivity barrier, and oxidation-reduction barrier. In some embodiments, the thin film has at least two of the desired properties. In other embodiments, the thin film has at least three of the desired properties. In some embodiments, the thin film has at least two of the desired properties. In other embodiments, the thin film has at least four of the desired properties.

In some preferred embodiments, two or more of the desired properties are provided by one layer. One such embodiment is illustrated in FIG. 24B. In other embodiments, two or more of the desired properties are provided by a plurality of layers. Reference may be had to FIG. 24A. In such embodiments, the thin film comprises at least two layers coated on and directly contacting said diamond, with the second layer directly contacting the first layer and the like.

By way of example, in one embodiment of the thin film, the diffusion barrier layer and said thermal barrier layer are the same layer. By way of further example, in one embodiment of the thin film, the diffusion barrier layer and said adhesion layer are the same layer. By way of further example, in one embodiment of the thin film, the diffusion barrier layer and said oxidation-reduction barrier layer are the same layer. By way of further example, in one embodiment of the thin film, the diffusion barrier layer and said chemical reactivity barrier layer are comprised of the same material.

In one embodiment, the plurality of coated layers are arranged so that the diamond coated with the thin film has a high thermal conductivity, prevents the diffusion of specie to or from the diamond, and has a thermal expansion coefficient different from diamond.

As used in this specification metals shall mean boron, copper, nickel, tungsten, molybdenum, titanium, hafnium and combinations thereof.

As used in this specification carbides of metals shall mean silicon carbide, boron carbide, tungsten carbide, molybdenum carbide, titanium carbide, nickel carbide, hafnium carbide and combinations thereof.

As used in this specification nitrides of metals shall mean boron nitride, silicon nitride, titanium nitride, hafnium nitride, aluminum nitride and combinations thereof.

As used in this specification oxides of metals shall mean quartz, alumina, silica, titanium oxide, hafnium oxide, and combinations thereof.

### Process for Depositing Thin Film on Diamond

### A Composite Diamond Substrate and Method of Adhering Diamond with Thin Film Deposited Thereon to a Semi-Conductor

In this section of the application, applicant will describe a process for depositing the aforementioned thin film on a diamond substance, adhering the thin film to a target material, and thereby producing a composite diamond substrate.

By way of illustration, but not limitation, in the composite diamond assembly, one may use a gas-phase synthesized polycrystalline diamond. In one embodiment, said gas-phase synthesized polycrystalline diamond is substantially free of chromium, aluminum, beryllium and titanium, all of which are impurities found in natural diamond. In a preferred embodiment, said diamond is produced by the methods described elsewhere in this specification.

It is to be understood that the diamond may be natural or synthetic and may be produced by any known method. It is to be further understood that said diamond may be monocrystalline or polycrystalline. In some embodiments, said diamond may be a diamond containing substance.

In a preferred embodiment, the diamond has a thermal conductivity greater than 1200 W/m-K.

In a preferred embodiment, one may use any of the thin films described elsewhere in this application. In particular, it is preferred to use thin films that enhance binding or that function as barriers against diffusion, thermal energy, chemical reactivity, oxidation-reduction, and combinations thereof. Alternatively, one may use any of the thin films with the desired properties known to those skilled in the art.

One may deposit the thin film on the diamond by the methods and processes described elsewhere in this specification. Alternatively, one may use any method of depositing a thin film known to those skilled in the art.

In one embodiment, one may use any semi-conductor wafer or individual device. By way of example, but not limitation, one may use a semi-conductor wafer comprised essentially of a multiplicity of devices. By way of further example, but not limitation, one may use a semi-conductor device such as the Intel Pentium model 560 available from Intel Corporation.

### EXAMPLE 1

A diamond deposition system was built using the following equipment and methods: A set of two Uniweld Products “All Trades II” V style Oxyacetylene outfits were employed, each of which consisted of a pair of hoses, an oxygen regulator, an acetylene regulator, a torch handle with internal gas mixing, and a set of welding tips ranging in size from 0 to 10; also utilized were four Aera FC-980 mass flow controllers, four DP 455C digital panel meters, four 3610C control potentiometers, and an Aera AS-60A water vapor delivery system, a copper block 6″×6″×1″ with an internal channel and a threaded input and output fitting for water-cooling, an Omega products SAT-12 platinum-rhodium 30 AWG thermocouple (ANSI type S) with an Al₂O₃ ceramic protection tube, a Keithley Instruments Model 2182 Nanovoltmeter, and a Keithley Instruments Model 248 High voltage power supply.

The Uniweld torch handle/mixer was attached to a tabletop clamp arm so that the welding tip was positioned above the copper block but pointing away from it. The welding tip used was the No. 0 tip with an orifice diameter of approximately 0.6-mm. The two hoses, one for oxygen and one for acetylene were attached to torch handle/mixer. The other end of each hose was attached via an adapter to the output side of an Aera FC-980 mass flow controller. Each mass flow controller was connected to a corresponding DP 455C digital panel meter and 3610C Control Potentiometer. The input side of one mass flow controller was connected to the regulator of an ACP400 Grade 2.6, 99.6% pure container of acetylene from National Welders Supply. The input side of the other mass flow controller was connected to the regulator of an Ultra High Purity Grade 4.4, 99.994% pure container of oxygen also from National Welders Supply. The input line of the copper block was attached to a tap water supply and the output was connected to a drain. The copper block itself had been modified on its face with a long groove through the center ⅛^{th} of an inch wide and ⅛^{th} of an inch deep and 6″ long. The thermocouple probe was placed in this groove so that its probe end was in the center of the block and the surface of the probe was flush with the surface of the block. A 2-cm by 2-cm piece of a silicon wafer was clamped to the center of the block using standard steel clamps. Prior to this, the silicon sample had been cleaned in and ultrasonic bath containing ethanol and then polished with Harris Diamond 1-10 micron grit powder.

To produce diamond, the valves of the torch handle were opened completely and the mass flow controllers were used as the means to control the flow of gas. After the tank regulators were opened, the 3610C control potentiometers were adjusted each to a flow rate of 1750 sccm per minute. The acetylene flame was then ignited. At this time the tap water source was opened. The flame was allowed to burn for 10 minutes in order for the gas mixture in the supply tanks to have time to stabilize. At this point the flame was observed to be neutral, i.e., having no acetylene-induced flame feather. The control potentiometer for the acetylene source was adjusted until the flame feather reached a length of approximately two centimeters. At this point the flow rate of acetylene was 1850 sccm, which gave a molar mass equivalency ratio between carbon to oxygen of 1.056. The tabletop clamp was then adjusted until the welding tip was pointing directly downward toward the copper block and the end of the flame feather was positioned approximately 2 millimeters from the silicon substrate. The tap water control was then adjusted until the temperature was stabilized at 900° C. according to the thermocouple probe. The oxy-acetylene torch was then allowed to operate for 30 minutes. After 30 minutes the gas flows were set to zero and the regulators closed.

After the oxy-acetylene torch was shut down, the silicon sample was allowed to cool for 30 minutes. The sample was then examined under a Carl Zeiss M2MAT Stereomicroscope. The examination revealed a bull's-eye pattern approximately 6 millimeters in diameter consisting of the following: (a) a region of continuous diamond of randomly oriented size and shapes in the center of the bull's-eye, with crystals approximately 1-10 microns in size extending from the center to about 3 millimeters from the center, (b) a region of dark balls mixed with small random crystals less than 1 micron, indicative of high graphitic carbon content extending from the previous region to about 4 millimeters from the center, and (c) a region of continuous randomly oriented diamond with octagonal shaped crystals on the outside edge, with crystals approximately 10-20 microns in size extending from the previous region to about 6 millimeters from the center.

### EXAMPLE 2

In accordance with the procedure described for Example 1, another experiment was performed using substantially the same conditions as Example 1 with the following conditions: (a) two welding tips from the Uniweld Products “All Trades II” V style Oxyacetylene torch set were connected to the original welding tip with a set of clamps, (b) these tips were placed parallel to the original, but on opposite sides so that they were 180 degrees apart with the original tip in the center, (c) the ends of the tip were recessed 1 mm from the end of the original tip, (d) the tips were size #6 with an opening diameter of approximately 2 millimeters, (e) the input sides of the tips were connected using brass tubing to two sides of a Y-connector, and the remaining end of the Y-connector was connected to the output port of a Uniweld Products torch handle with internal gas mixing, (f) one of the input ports of the torch handle/mixer was connected directly via a hose and adapter to an Aera FC-980 mass flow controller (g) this mass flow controller was then connected to the regulator of a bottle of Ultra High Purity Grade 5.0, 99.999% purity hydrogen from National Welders Supply, (h) the second input port of torch handle/mixer was connected via a hose and adapter to a T-connector, (i) one side of this T-connector was attached to an Aera FC-980 mass flow controller, 0) the input side of the other mass flow controller was connected to the regulator of another Ultra High Purity Grade 4.4, 99.994% pure container of oxygen also from National Welders Supply, and (k) the other side of the T-connector was connected to the output port of an Aera AS-60A water vapor delivery system. In total the system consisted of one nozzle burning oxygen and acetylene, and two adjacent nozzles burning oxygen and hydrogen with the addition of water vapor.

In order to produce diamond, substantially the same steps were used as described for Example 1, with the following conditions being used: (a) after the torch had been properly positioned above the silicon sample with the flame feather 2 millimeters from the surface, and after the temperature was stabilized, the water vapor, oxygen and hydrogen sources were activated, (b) the control potentiometer was used to set the oxygen flow through the mass flow controller at 3500 sccm, (c) the control potentiometer was used to set the hydrogen flow through the mass flow controller at 3700 sccm, and the settings on the water vapor delivery system were adjusted to provide a flow of 400 sccm which is the equivalent of 5.56% mass of the total, (d) ignition of the mixture occurred upon contact with the existing oxy-acetylene flame, (e) the tap water flow into the cooling block was then readjusted to maintain the measured temperature at 900° C., (f) the oxy-acetylene torch was then allowed to operate for 30 minutes, and (g) after 30 minutes the gas flows were set to zero and the regulators closed.

After the oxy-acetylene torch was shut down, the silicon sample was allowed to cool for 30 minutes. The sample was the examined under a Carl Zeiss M2MAT Stereomicroscope. The examination revealed an hourglass pattern about 9 millimeters long with the following properties: (a) a region of continuous diamond of randomly oriented size and shapes in the center (narrow) region of the hourglass, with crystals approximately 1-10 microns in size, which center region corresponded to the point directly under the central oxy-acetylene torch tip, and (b) a region of continuous randomly oriented diamond extending from the narrow region of the hourglass to the broad regions of the top and bottom of the hourglass. These broad regions of the top and bottom of the hourglass corresponded to the areas directly under the oxy-hydrogen torch tips. The orientation of these crystals became more uniform and assumed more of an octagonal shape as they approached outside edge of the top and bottom of the hourglass pattern. The size of these crystals grew from 1-10 microns to approximately 15-20 microns in size as they approached outside edge of the top and bottom of the hourglass pattern.

A region of dark balls mixed with small random crystals less than 1 micron was present on each side of the hourglass pattern, starting about 1 millimeter from the center extending out about 4 millimeters from the center. The properties of this region appeared to be indistinguishable from those the graphitic carbon region described in Example 1, except for the extension of this region from the center as noted previously.

Also found were two regions of continuous randomly oriented diamond with octagonal shaped crystals on the outside edge, with crystals approximately 10-20 microns in size. Each region was oval shaped and abutted, extending previous region outward for about 2 millimeters from the previous region. The properties of this region appeared to be indistinguishable from those the continuous randomly oriented diamond region on the outside of the bull's-eye as described in Example 1, except for the extension and shape of this region as noted previously.

### EXAMPLE 3

Another experiment was performed using substantially the same conditions those described in Example 1 with the following differences:

Three aluminum silicate ceramic pipes 3 inches long and ½ inch in diameter were obtained. The ends of these pipes were machined with a standard sized threading. The ends of these pipes were then fitted with stainless steel adapters and threads were sealed with an epoxy compound. These pipes were then connected between the welding torch tips and the torch handle/mixer. These pipes served to electrically insulate the torch tips from the remaining equipment and ground. The tabletop clamp arm was then readjusted so the position of the torch tip was the same as that described in Example 1.

A Keithley Instruments Model 248 High voltage power supply was connected between the tip and the substrate. The positive terminal was connected to the torch tip by clamping a copper wire with the sheath removed from the last 8″ to the input side of the tip. The negative terminal was electrically connected to the silicon sample by connecting it physically to the four steel clamps that hold the sample in place. The copper cooling block was placed on an insulating surface and the nylon water hose to the copper block provided electrical insulation. In this manner the silicon sample was isolated from electrical ground.

To produce diamond the same steps were used as outlined in Example 1 with the following differences, described below.

After the torch had been properly positioned above the silicon sample with the flame feather 2 millimeters from the surface, and after the temperature was stabilized, the Model 248 high voltage power supply was activated. The voltage was increased and the current was monitored. At a voltage of 250V the ammeter on the power supply detected an initial current in the microamp range. At a voltage of 870V the ammeter on the power supply registered a current of about 1 milliamp. After this point the current began to rise rapidly. At a voltage of 1340V the ammeter on the power supply registered a current of about 50 milliamps. No change was detected in the temperature of the substrate as measured by the thermocouple. The oxy-acetylene torch was then allowed to operate for 30 minutes. After 30 minutes the gas flows were set to zero, the regulators closed, and the power supply was shut off. After the oxy-acetylene torch was shut down, silicon sample was allowed to cool for 30 minutes.

A sample prepared under the conditions given in Example 1 and a sample prepared under the conditions given in Example 3 were both scribed on the back sides using a straight edge and a diamond tipped scribe. The scribe mark was placed to run directly through the center of the diamond deposit on each sample. The samples were then snapped in half along the scribe mark and through the deposited diamond. The samples were then examined under a Carl Zeiss M2MAT Stereomicroscope under high magnification. Using a 50-micron wide gold wire as a size reference, the thickness of the diamond deposit in the center of the sample was estimated. The sample prepared under the conditions given in Example 1 had a thickness of approximately 250 microns at its thickest point. Using the same measurement conditions the sample prepared under the conditions given in Example 1 had a thickness of approximately 550 microns at its thickest point.

It is to be understood that the aforementioned description is illustrative only and that changes can be made in the apparatus, in the ingredients and their proportions, and in the sequence of combinations and process steps, as well as in other aspects of the invention discussed herein, without departing from the scope of the invention.

I claim:

1. A process of producing a diamond substance, comprising the steps of:
a. forming a first mixture comprised of oxygen gas and a hydrocarbon gas, wherein said hydrocarbon gas contains from about one percent to about ten percent molar excess of carbon for each mole of oxygen present in such first mixture;
b. igniting said first mixture to produce a flame core;
c. forming a second mixture comprised of hydrogen and oxygen, wherein:
1. said second mixture is comprised of a molar excess of said hydrogen over the moles of said oxygen present in the second mixture,
2. said second mixture contains up to about 10 volume percent of hydrocarbon gas;
d. igniting said second mixture to produce a flame sheath;
e. disposing said flame sheath around said flame core so that said flame sheath surrounds said flame core and shields said flame core from the atmosphere, thereby producing a composite flame; and
f. contacting said composite flame with a substrate.

2. The process of producing a diamond substance as recited in claim 1, wherein said flame core has a temperature of at least about 2,000 degrees centigrade.

3. The process of producing a diamond substance as recited in claim 2, wherein said flame sheath has a temperature of at least about 250 degrees centigrade.

4. The process of producing a diamond substance as recited in claim 1, wherein said substrate is comprised of semiconductor.

5. The process of producing a diamond substance as recited in claim 1, wherein said substrate comprises a material selected from the group consisting of boron, copper, nickel, tungsten, molybdenum, titanium, hafnium, silicon carbide, boron carbide, tungsten carbide, molybdenum carbide, titanium carbide, nickel carbide, hafnium carbide, boron nitride, silicon nitride, titanium nitride, hafnium nitride, aluminum nitride, quartz, alumina, silica, titanium oxide, hafnium oxide, and combinations thereof.

6. A process of producing a diamond substance, comprising the steps of:
a. forming a first mixture comprised of oxygen gas and a hydrocarbon gas, wherein said hydrocarbon gas contains from about one percent to about ten percent molar excess of carbon for each mole of oxygen present in such first mixture;
b. igniting said first mixture to produce a flame core;
c. forming a second mixture comprised of hydrogen and oxygen, wherein:
1. said second mixture is comprised of a molar excess of said hydrogen over the moles of said oxygen present in the second mixture,
2. said second mixture contains up to about 10 volume percent of hydrocarbon gas;
d. igniting said second mixture to produce a flame sheath;
e. disposing said flame sheath around said flame core so that said flame sheath surrounds said flame core and shields said flame core from the atmosphere, thereby producing a composite flame;
f. contacting said composite flame with a substrate, wherein
1. said substrate is comprised of a semi-conductor;
2. said substrate is comprised of an adhesion layer for adhering said semi-conductor to said diamond substance; and
3. said substrate comprises a material selected from the group consisting of boron, copper, nickel, tungsten, molybdenum, titanium, hafnium, silicon carbide, boron carbide, tungsten carbide, molybdenum carbide, titanium carbide, nickel carbide, hafnium carbide, boron nitride, silicon nitride, titanium nitride, hafnium nitride, aluminum nitride, quartz, alumina, silica, titanium oxide, hafnium oxide, and combinations thereof.

7. The process of producing a diamond substance as recited in claim 6, wherein said substrate is further comprised of a first barrier layer selected from the group consisting of a diffusion barrier layer, a thermal barrier layer, a chemical reactivity barrier layer, an oxidation-reduction carrier layer, and combinations thereof.

8. A process of producing a diamond substance, comprising the steps of:
a. forming a first mixture comprised of oxygen gas and a hydrocarbon gas, wherein said hydrocarbon gas contains from about one percent to about ten percent molar excess of carbon for each mole of oxygen present in such first mixture;
b. igniting said first mixture to produce a flame core;
c. forming a second mixture comprised of hydrogen and oxygen, wherein:
1. said second mixture is comprised of a molar excess of said hydrogen over the moles of said oxygen present in the second mixture,
2. said second mixture contains up to about 10 volume percent of hydrocarbon gas;
d. igniting said second mixture to produce a flame sheath;
e. disposing said flame sheath around said flame core so that said flame sheath surrounds said flame core and shields said flame core from the atmosphere, thereby producing a composite flame;
f. contacting said composite flame with a substrate, wherein
1. said substrate is comprised of a semi-conductor;
2. said substrate is comprised of an adhesion layer for adhering said semi-conductor to said diamond substance;
3. said substrate is further comprised of a first barrier layer selected from the group consisting of a diffusion barrier layer, a thermal barrier layer, a chemical reactivity barrier layer, an oxidation-reduction carrier layer, and combinations thereof, and
4. said substrate is further comprised of a second barrier layer selected from the group consisting of a diffusion barrier layer, a thermal barrier layer, a chemical reactivity barrier layer, an oxidation-reduction carrier layer, and combinations thereof.

9. An apparatus for forming a diamond substance comprising a torch assembly comprised of
a. a first nozzle for forming a first mixture comprised of oxygen gas and a hydrocarbon gas, wherein said hydrocarbon gas contains from about one percent to about ten percent molar excess of carbon for each mole of oxygen present in such first mixture;
b. a first igniter for igniting said first mixture to produce a flame core;
c. a second nozzle for forming a second mixture comprised of hydrogen and oxygen, wherein:
1. said second mixture is comprised of a molar excess of said hydrogen over the moles of said oxygen present in the second mixture,
2. said second mixture contains up to about 10 volume percent of hydrocarbon gas;
d. a second igniter for igniting said second mixture to produce a flame sheath;
e. a torch opening for disposing said flame sheath around said flame core so that said flame sheath surrounds said flame core and shields said flame core from the atmosphere, thereby producing a composite flame.

10. The apparatus for producing a diamond substance as recited in claim 9, wherein said apparatus is disposed above a substrate such that said substrate is in contact with said composite flame, thereby contacting said composite flame with said substrate.

11. The apparatus for producing a diamond substance as recited in claim 10, wherein
a. said substrate is comprised of a semi-conductor;
b. said substrate is comprised of an adhesion layer for adhering said semi-conductor to said diamond substance.
c. said substrate is further comprised of a first barrier layer selected from the group consisting of a diffusion barrier layer, a thermal barrier layer, a chemical reactivity barrier layer, an oxidation-reduction carrier layer, and combinations thereof.

12. The apparatus as recited in claim 9, wherein said apparatus is further comprised of a first flow control valve for controlling the flow rate of said first mixture.

13. The apparatus as recited in claim 12, wherein said apparatus is further comprised of a second flow control valve for controlling the flow rate of said second mixture.

14. The apparatus as recited in claim 13, wherein said apparatus is further comprised of a variable geometry sub-nozzle for adjusting the geometry of said flame sheath.

15. The apparatus as recited in claim 9, further comprising a deposition area with a deposition surface.

16. The apparatus as recited in claim 15, wherein said deposition area is a stationary deposition area and said apparatus is moved over said deposition surface.

17. The apparatus as recited in claim 15, wherein said deposition area is a mobile deposition area and said deposition area is moved relative to said apparatus.

18. The apparatus as recited in claim 15, wherein said deposition area has a long axis and said apparatus has an axis of rotation such that said apparatus is rotatable relative to said long axis.

19. The apparatus as recited in claim 9, wherein said apparatus is comprised of a plurality of said torch assemblies.

20. The apparatus as recited in claim 19, further comprising means for applying an electric field to said flame core and said flame sheath.
